(19) United States
(12) Patent Application Publication
(10) Pub. No.: US 2023/0176362 A1
(43) Pub. Date: Jun. 8, 2023

(54) SCANNING OPTICAL DEVICE AND METHOD FOR MAKING SCANNING OPTICAL DEVICE

(71) Applicant: BROTHER KOGYO KABUSHIKI KAISHA, Nagoya (JP)

(72) Inventors: Koji ABE, Okazaki (JP); Yoshihiro OYAMA, Tokyo (JP); Junichi YOKOI, Nagoya (JP)

(73) Assignee: BROTHER KOGYO KABUSHIKI KAISHA, Nagoya (JP)

(21) Appl. No.: 18/061,061

(22) Filed: Dec. 2, 2022

(30) Foreign Application Priority Data
Dec. 6, 2021 (JP) 2021-197608
Dec. 6, 2021 (JP) 2021-197609
Dec. 6, 2021 (JP) 2021-197611

(51) Int. Cl. G02B 26/12; H01S 5/40; H01S 5/00

(52) U.S. Cl. CPC G02B 26/123; G02B 26/124; H01S 5/40; H01S 5/0071

(57) ABSTRACT

A scanning optical device proposed herein includes first and second semiconductor lasers, first and second coupling lenses, a polygon mirror, and first and second holders. The first and second coupling lenses convert light emitted by the first and second semiconductor lasers into light beams, respectively. The polygon mirror deflects the light beams received from the first and second coupling lenses. The first holder has a seating surface on which the first coupling lens is fixed by a photo-curable resin. The second holder is configured to hold the second coupling lens in such a position that the first and second coupling lenses are arranged in a line parallel to a rotation axis of the polygon mirror. The second holder is fixed to the first holder by a photo-curable resin.

### REFERENCE TO RELATED APPLICATIONS

This application claims priority from Japanese Patent Application Nos. 2021-197608, 2021-197611, 2021-197609, and 2021-197610, filed on Dec. 6, 2021. The entire contents of the priority applications are incorporated herein by reference.

### BACKGROUND ART

A scanning optical device comprising a plurality of semiconductor lasers and a plurality of coupling lenses is known in the art. In one specific example, a scanning optical device includes a holder having two semiconductor lasers press-fitted therein, and the holder has two seating surfaces to which two coupling lenses are attached respectively. The holder includes a wall positioned between the two coupling lenses, and opposite side surfaces of the wall serve as the seating surfaces for attachment of the corresponding coupling lenses.

The scanning optical device may comprise a frame to which the holder is attached. Specifically, the holder may have a locating surface, and include a cylindrical portion protruding from the locating surface and a protrusion protruding from the locating surface. On the other hand, the frame may have an attachment hole and a locating hole, and include three bosses. The three bosses and the locating hole are positioned around the attachment hole. When the holder is attached to the frame by fitting the cylindrical portion of the holder into the attachment hole of the frame, the three bosses of the frame contact the locating surface of the holder, and the protrusion of the holder is inserted into the locating hole of the frame to restrain rotation (angular displacement) of the holder, so that the holder is located in place relative to the frame.

A scanning optical device may comprise a polygon mirror, and an aperture stop configured to define a size of a light beam incident on the polygon mirror may be formed in and integrally with a frame of the scanning optical device. To form the aperture stop in the frame, an insert is slid in a direction perpendicular to a mold's opening/closing direction in the process of molding the frame.

### DESCRIPTION

In the process of making a scanning optical device, the seating surfaces provided on the opposite sides of the wall of the holder as described above makes it necessary to take steps of attaching one coupling lens to the seating surface on one side of the wall and then attaching another coupling lens to the seating surface on the other side of the wall, which would be complicated and burdensome.

It would be desirable to provide an improved structure of the scanning optical device in which a plurality of coupling lenses can be attached on one and the same side so that complicated work in the process of making the scanning optical device can be obviated.

From this point of view, a scanning optical device proposed herein comprises a first semiconductor laser configured to emit light, a second semiconductor laser configured to emit light, a first coupling lens configured to convert the light emitted by the first semiconductor laser into a light beam, a second coupling lens configured to convert light emitted by the second semiconductor laser into a light beam, a polygon mirror configured to deflect the light beam received from the first coupling lens and the light beam received from the second coupling lens, a first holder configured to hold the first coupling lens, and a second holder configured to hold the second coupling lens. The first holder has a seating surface on which the first coupling lens is fixed by a photo-curable resin. The second coupling lens held by the second holder is located in such a position that the first coupling lens and the second coupling lens are arranged in a line parallel to a rotation axis of the polygon mirror. The second holder is fixed to the first holder by a photo-curable resin.

With this configuration, the first coupling lens can be carried in a predetermined direction toward and attached to the seating surface of the first holder, and then the second holder holding the second coupling lens can be carried in the same predetermined direction toward and attached to the first holder. Thus, a plurality of coupling lenses can be attached on one and the same side so that complicated work can be obviated in the process of making the scanning optical device.

In the scanning optical device configured as described above, the seating surface may be a flat surface perpendicular to the rotation axis.

In the scanning optical device configured as described above, the second holder may comprise a lens attachment to which the second coupling lens is attached, and a leg extending from the lens attachment to the seating surface. The leg may be fixed on the seating surface by a photo-curable resin.

With this configuration, in which the leg extending from the lens attachment is provided in the second holder, an undesirable collision of the lens attachment with the first coupling lens can be made less likely to occur.

The leg mentioned above may comprise a first leg and a second leg located in a position separate from the first leg in a perpendicular direction perpendicular to the rotation axis and to an optical axis of the first semiconductor laser, such that light traveling from the first semiconductor laser to the first coupling lens passes through a gap formed between the first leg and the second leg.

With this configuration, the second coupling lens can be held stably by the second holder having its two legs fixed on the seating surface.

The second holder may be made of a material that allows light for curing the photo-curable resin to pass therethrough.

With this configuration, light for curing the photo-curable resin can be applied through the second holder to the photo-curable resin to cure the photo-curable resin, so that the second holder can be fixed to the first holder with ease.

The first holder may hold the first semiconductor laser and the second semiconductor laser arranged in a line parallel to the rotation axis of the polygon mirror. The first holder may comprise a first portion having the seating surface, and a second portion extending from the first portion in a direction parallel to the rotation axis and configured to hold the first semiconductor laser and the second semiconductor laser.

With this configuration, a portion which holds the first semiconductor laser and a portion having the seating surface on which the first coupling lens is fixed can be integrally formed of a single part, so that the first coupling lens can be located in place relative to the first semiconductor laser with increased precision.

The first holder and the second holder may be made of plastic.

With this feature, the first holder and the second holder can be formed to have the same linear expansivity, so that undesirable deviation in relative positions of the first coupling lens and the second coupling lens due to linear expansion of the first and second holders can be minimized.

In another aspect, a method for making a scanning optical device having a first semiconductor laser, a second semiconductor laser, a first coupling lens, a second coupling lens and a polygon mirror, in which light emitted by the first semiconductor laser is converted by the first coupling lens into a light beam and light emitted by the second semiconductor laser is converted by the second coupling lens into a light beam, and the light beams received from the first coupling lens and the second coupling lens are deflected by the polygon mirror is proposed.

This method comprises: providing a first holder configured to hold the first coupling lens, the first holder having a seating surface; providing a second holder configured to hold the second coupling lens, in such a position that the first coupling lens and the second coupling lens are arranged in a line parallel to a rotation axis of the polygon mirror; locating the first coupling lens in place relative to the first semiconductor laser, and fixing the first coupling lens to the seating surface of the first holder, e.g., by bonding (first bonding process); attaching the second coupling lens to the second holder; and locating the second coupling lens attached to the second holder in place relative to the second semiconductor laser, and fixing the second holder to the first holder, e.g., by bonding (second bonding process).

With this method, the first coupling lens can be carried in a predetermined direction toward and attached to the seating surface of the first holder, and then the second holder holding the second coupling lens can be carried in the same predetermined direction toward and attached to the first holder. Thus, a plurality of coupling lenses can be attached on one and the same side so that complicated work can be obviated in the process of making the scanning optical device.

The first bonding process of locating and fixing the first coupling lens may comprise: placing a photo-curable resin between the first coupling lens and the seating surface; and adjusting a position of the first coupling lens relative to the first semiconductor laser, and thereafter applying light to the photo-curable resin to fix the first coupling lens to the seating surface, and the second bonding process of locating the second coupling lens and fixing the second holder may comprise: placing a photo-curable resin between the first holder and the second holder; and adjusting a position of the second coupling lens relative to the second semiconductor laser, and thereafter applying light to the photo-curable resin to fix the second holder to the first holder.

The locating the first coupling lens in place may comprise adjusting a position of the first coupling lens relative to the first semiconductor laser by using a jig holding the first coupling lens at two ends thereof facing in opposite directions parallel to a perpendicular direction perpendicular to the rotation axis and to an optical axis of the first semiconductor laser.

In addition, the locating the second coupling lens in place may comprise adjusting a position of the second coupling lens relative to the second semiconductor laser by using the jig holding the second holder at two ends thereof facing in opposite directions parallel to the perpendicular direction.

In still another aspect, a scanning optical device comprising a first semiconductor laser, a second semiconductor laser, a first coupling lens, a second coupling lens, a deflector, a frame, a first holder, and a second holder is proposed herein. The first semiconductor laser is configured to emit light, and the first coupling lens is configured to convert the light emitted by the first semiconductor laser into a light beam. The second semiconductor laser is configured to emit light, and the second coupling lens is configured to convert the light emitted by the second semiconductor laser into a light beam. The deflector comprises a polygon mirror configured to deflect the light beam received from the first coupling lens and the light beam received from the second coupling lens. The deflector is fixed to the frame. The first holder is configured to hold the first coupling lens. The first holder has a first seating surface on which the first coupling lens is fixed by a photo-curable resin. The second holder is configured to hold the second coupling lens, in such a position that the first coupling lens and the second coupling lens are arranged in a line parallel to a rotation axis of the polygon mirror. The second holder has a second seating surface on which the second coupling lens is fixed by a photo-curable resin. The second holder is fixed to the frame.

With this configuration, the first coupling lens can be carried in a predetermined direction toward and attached to the first seating surface of the first holder, and the second coupling lens can be carried in the same predetermined direction toward and attached to the second holder previously attached to the frame. Thus, a plurality of coupling lenses can be attached on one and the same side so that complicated work can be obviated in the process of making the scanning optical device.

In the scanning optical device configured as described above, each of the first seating surface and the second seating surface may be configured as a flat surface perpendicular to the rotation axis.

In the scanning optical device configured as described above, the second holder may comprise: a base having the second seating surface; and a leg extending from the base in a direction opposite to a direction in which the second seating surface faces. The leg may be fixed to the frame.

With this configuration, in which the leg extending from the base is provided in the second holder, an undesirable collision of the base with the first coupling lens can be made less likely to occur.

The leg mentioned above may comprise a first leg and a second leg located in a position, separate from the first leg in a perpendicular direction perpendicular to the rotation axis and to an optical axis of the first semiconductor laser, such that light traveling from the first semiconductor laser to the first coupling lens passes through a gap formed between the first leg and the second leg.

With this configuration, the second coupling lens can be held stably by the second holder having its two legs fixed to the frame.

The first holder may hold the first semiconductor laser and the second semiconductor laser arranged in a line parallel to the rotation axis of the polygon mirror. The first holder may comprise a first portion having the first seating surface, and a second portion extending from the first portion in a direction parallel to the rotation axis, and configured to hold the first semiconductor laser and the second semiconductor laser.

With this configuration, a portion which holds the first semiconductor laser and a portion having the first seating surface on which the first coupling lens is fixed can be integrally formed of a single part, so that the first coupling lens can be located in place relative to the first semiconductor laser with increased precision.

The frame may comprise a first locating surface and a second restraining portion. The first locating surface is a surface with which the first holder is positioned in a first predetermined direction. The second restraining portion is a portion with which the second holder is positioned in the first predetermined direction. The second restraining portion is located in such a position that a first plane containing the first locating surface intersects with the second restraining portion.

With this configuration, the second restraining portion is located in approximately the same position as that of the first locating surface with respect to the positions in the first predetermined direction, and thus the influence of thermal expansion of the holders on positioning accuracy in the first predetermined direction can be reduced.

The frame may comprise a first restraining portion and a second locating surface. The first restraining portion is a portion with which the first holder is positioned in a second predetermined direction. The second locating surface is a surface with which the second holder is positioned in the second predetermined direction. The first restraining portion is located in such a position that a second plane containing the second locating surface intersects with the first restraining portion.

With this configuration, the first restraining portion is located in approximately the same position as that of the second locating surface with respect to the positions in the second predetermined direction, and thus the influence of thermal expansion of the holders on positioning accuracy in the second predetermined direction can be reduced.

The second holder may be fixed to the frame by a screw.

The scanning optical device as described above may further comprise a third semiconductor laser, a fourth semiconductor laser, a third coupling lens, and a fourth coupling lens. The third semiconductor laser is configured to emit light and the third coupling lens is configured to convert the light emitted by the third semiconductor laser into a light beam. The fourth semiconductor laser is configured to emit light, and the fourth coupling lens is configured to convert the light emitted by the fourth semiconductor laser into a light beam. The second semiconductor laser and the third semiconductor laser are arranged in a line parallel to a perpendicular direction perpendicular to an optical axis of the first semiconductor laser and to the rotation axis. The first semiconductor laser and the fourth semiconductor laser are arranged in a line parallel to the perpendicular direction. The third semiconductor laser and the fourth semiconductor laser are arranged in a line parallel to the rotation axis. The third coupling lens is fixed on the second seating surface by a photo-curable resin.

With this configuration, in which the second coupling lens and the third coupling lens are fixed on the second seating surface of the second holder, the number of parts can be reduced in comparison with an alternative configuration, for example, in which the third coupling lens is fixed to another member provided separately from the second holder.

In still another aspect, a method for making a scanning optical device having a first semiconductor laser, a second semiconductor laser, a first coupling lens, a second coupling lens, a frame, a deflector including a polygon mirror and fixed to the frame, a first holder, and a second holder, in which light emitted by the first semiconductor laser is converted by the first coupling lens into a light beam and light emitted by the second semiconductor laser is converted by the second coupling lens into a light beam, and the light beams received from the first coupling lens and the second coupling lens are deflected by the polygon mirror is proposed. Herein the first semiconductor laser and the second semiconductor laser may be arranged in a line parallel to a rotation axis of the polygon mirror.

This method comprises: providing a first holder having a first seating surface and configured to hold the first coupling lens; providing a second holder having a second seating surface and configured to hold the second coupling lens, in such a position that the first coupling lens and the second coupling lens are arranged in a line parallel to the rotation axis of the polygon mirror; locating the first coupling lens in place relative to the first semiconductor laser, and fixing the first coupling lens on the first seating surface of the first holder, e.g., by bonding (first bonding process); attaching the second holder to frame (attaching process); and locating the second coupling lens in place relative to the second semiconductor laser, and fixing the second coupling lens on the second seating surface of the second holder, e.g., by bonding (second bonding process).

With this method, the first coupling lens can be carried in a predetermined direction toward and attached to the first seating surface of the first holder, and the second coupling lens can be carried in the same predetermined direction toward and attached to the second holder previously attached to the frame. Thus, a plurality of coupling lenses can be attached on one and the same side so that complicated work can be obviated in the process of making the scanning optical device.

The first bonding process of locating and fixing the first coupling lens may comprise: placing a photo-curable resin between the first coupling lens and the first seating surface; and adjusting a position of the first coupling lens relative to the first semiconductor laser, and thereafter applying light to the photo-curable resin to fix the first coupling lens to the first seating surface, and the second bonding process of locating and fixing the second coupling lens may comprise: placing a photo-curable resin between the second coupling lens and the second seating surface; and adjusting a position of the second coupling lens relative to the second semiconductor laser, and thereafter applying light to the photo-curable resin to fix the second coupling lens to the second seating surface.

The locating the first coupling lens in place may comprise adjusting a position of the first coupling lens relative to the first semiconductor laser by using a jig holding the first coupling lens at two ends thereof facing in opposite directions parallel to a perpendicular direction perpendicular to the rotation axis and to an optical axis of the first semiconductor laser.

In addition, the locating the second coupling lens in place may comprise adjusting a position of the second coupling lens relative to the second semiconductor laser by using the jig holding the second holder at two ends thereof facing in opposite directions parallel to the perpendicular direction.

In the scanning optical device with a frame having a plurality of locating portions (e.g., attachment hole, and three bosses and locating hole arranged around the attachment hole, as mentioned above) to which a laser holder is fitted and located in place, the locating portions are not aligned with a plurality of semiconductor lasers or provided along a direction of arrangement of the plurality of semiconductor lasers, but are rather arranged irregularly. This would increase the difficulty in precise tolerance management.

It would be desirable to facilitate tolerance management.

From this point of view, a scanning optical device comprising a first semiconductor laser configured to emit light, a second semiconductor laser configured to emit light, a deflector comprising a polygon mirror configured to deflect the light from the first semiconductor laser and the light from the second semiconductor laser, a frame to which the deflector is fixed, and a laser holder configured to hold the first semiconductor laser and the second semiconductor laser is proposed herein. The laser holder includes a first holder locating portion and a second holder locating portion. The first holder locating portion and the second holder locating portion are located in place with respect to the frame. The first semiconductor laser, the second semiconductor laser, the first holder locating portion, and the second holder locating portion are arranged in a line parallel to a direction of arrangement of the first semiconductor laser and the second semiconductor laser.

With this configuration, the holder locating portions and the semiconductor lasers are aligned with the line parallel to the direction of arrangement of the semiconductor lasers; thus, the tolerance management can be facilitated.

Specifically, the first semiconductor laser and the second semiconductor laser may be located between the first holder locating portion and the second holder locating portion in the line parallel to the direction of arrangement.

The direction of arrangement may be parallel to a rotation axis of the polygon mirror.

With this configuration, the first semiconductor laser and the second semiconductor laser are arranged in the sub-scanning direction; therefore, the first semiconductor laser for exposure at a first image plane and the second semiconductor laser for exposure at a second image plane different from the first image plane can be attached to one and the same laser holder.

The frame may comprise a first contact portion that contacts the first holder locating portion in a direction parallel to an optical axis of the first semiconductor laser.

With this configuration, the positioning of the laser holder relative to the frame in the direction parallel to the optical axis of the first semiconductor laser can be achieved.

One of the first holder locating portion and the first contact portion may be a boss, and the other of the first holder locating portion and the first contact portion may have a hole in which the boss is fitted.

The first holder locating portion may be fixed to the frame by a screw applied in a direction parallel to an optical axis of the first semiconductor laser.

The frame may comprise a second contact portion that contacts the second holder locating portion in a perpendicular direction perpendicular to an optical axis of the first semiconductor laser to a rotation axis of the polygon mirror.

With this configuration, rotation or angular displacement of the laser holder relative to the frame can be restrained.

The scanning optical device may further comprise a first coupling lens configured to convert the light emitted by the first semiconductor laser into a light beam, and a second coupling lens configured to convert the light emitted by the second semiconductor laser into a light beam. The laser holder may comprise a first portion having a seating surface on which the first coupling lens is fixed, and a second portion extending from the first portion in a direction parallel to the rotation axis of the polygon mirror and configured to hold the first semiconductor laser and the second semiconductor laser.

With this configuration, a portion which holds the first semiconductor laser and a portion having the seating surface on which the first coupling lens is fixed can be integrally formed of a single part, so that the first coupling lens can be located in place relative to the first semiconductor laser with increased precision.

The first coupling lens may be fixed on the seating surface by a photo-curable resin.

With this configuration, the first coupling lens can be located in place and fixed on the seating surface by applying light to the photo-curable resin after adjustment in position of the first coupling lens relative to the first semiconductor laser.

The first portion may be spaced apart from the frame with a gap provided therebetween in a direction of the rotation axis of the polygon mirror.

With this configuration, the tolerance of the frame and the laser holder would not affect the seating surface of the first coupling lens.

The first semiconductor laser may be located between the second semiconductor laser and the first holder locating portion arranged in the line parallel to the direction of arrangement, and the first portion may be located between the first semiconductor laser and the first holder locating portion arranged in the line parallel to the direction of arrangement.

The laser holder may be made of plastic.

With this feature, the laser holder can be shaped with increased flexibility, and the expansivity thereof can be specified from a wide range of values.

In the scanning optical device having a frame formed with a locating portion for locating a semiconductor laser in place and an aperture stop formed by using a dedicated insert which does not serve to form the locating portion, the accuracy in relative positions of the locating portion and the aperture stop in the frame would be difficult to insure.

It would be desirable to increase the positioning accuracy for the locating portion for locating the semiconductor laser and the aperture stop.

From this point of view, a scanning optical device proposed herein comprises: a semiconductor laser configured to emit light; a coupling lens configured to convert light emitted by the semiconductor laser into a light beam; a deflector including a polygon mirror configured to deflect the light beam received from the coupling lens; a plastic frame to which the deflector is fixed; a laser holder configured to hold the semiconductor laser; a diaphragm formed integrally with the frame and having an aperture stop positioned to allow the light beam to pass therethrough; and a locating portion formed integrally with the frame and having a shape protuberant or recessed in a direction parallel to an optical axis of the semiconductor laser to locate the laser holder in place. The aperture stop and the locating portion provided integrally with the frame are seen from outside of the frame in the direction parallel to the optical axis when no other member is attached to the frame.

With this configuration, the aperture stop and the locating portion can be formed by using one and the same insert, with the result that the positioning accuracy for the aperture stop and the locating portion can be increased.

The aperture stop and the locating portion may be arranged along a straight line parallel to the rotation axis of the polygon mirror as seen in the direction parallel to the optical axis.

The locating portion may comprise a first contact portion that contacts the laser holder in a direction parallel to the optical axis, and a second contact portion that contacts the laser holder in a perpendicular direction perpendicular to the optical axis and to a rotation axis of the polygon mirror, wherein the aperture stop is positioned between the first contact portion and the second contact portion arranged parallel to the optical axis.

The first contact portion may be a boss in which a screw is inserted at a center thereof.

The laser holder may be configured to hold a plurality of semiconductor lasers, and the diaphragm may have a plurality of aperture stops corresponding to the plurality of semiconductor lasers.

The scanning optical device may further comprise a condenser lens located between the aperture stop (or each aperture stop) and the polygon mirror, and configured to condense a light beam received from the coupling lens, in a sub-scanning direction, wherein an aperture formed to define the aperture stop (or each aperture stop) in the diaphragm may have a first open edge farther from the condenser lens and a second open edge closer to the condenser lens which is smaller than the first open edge.

With this configuration, the size of the second open edge of the aperture as the size of the aperture stop can be made to conform to dimensional requirements.

The laser holder may be configured to hold the coupling lens.

The frame may comprise a sidewall defining one side of the frame which is located in a position of which a distance from the locating portion is shorter than a distance from the deflector. More specifically, the sidewall and the deflector may be located on opposite sides of the locating portion. The sidewall may have an opening through which the aperture stop(s) and the locating portion are exposed and accessible from outside.

With this configuration, the rigidity of the frame can be increased by the sidewall, while the aperture stop(s) and the locating portion can be formed by using one and the same insert.

In another aspect, a method for making a scanning optical device is proposed herein. The scanning optical device comprises: a semiconductor laser configured to emit light; a coupling lens configured to convert light emitted by the semiconductor laser into a light beam; a deflector including a polygon mirror configured to deflect the light beam received from the coupling lens; a plastic frame to which the deflector is fixed; a laser holder configured to hold the semiconductor laser; a diaphragm formed integrally with the frame and having an aperture stop positioned to allow the light beam to pass therethrough; and a locating portion formed integrally with the frame and having a shape protuberant or recessed in a direction parallel to an optical axis of the semiconductor laser to locate the laser holder in place. The aperture stop and the locating portion provided integrally with the frame are seen from outside of the frame in the direction parallel to the optical axis when no other member is attached to the frame. The method comprises: providing an insert having a first mold surface for forming the aperture stop and a second mold surface for forming the locating portion, the first mold surface and the second mold surface being provided integrally in the insert; and performing injection molding with the insert, whereby the aperture stop and the locating portion are formed integrally in the frame.

With this method, the aperture stop and the locating portion are formed by using one and the same insert, and thus the positioning accuracy for the aperture stop and the locating portion can be increased.

The method may further comprise: providing a first mold contoured to form a first side of the frame facing in one of two opposite directions parallel to the rotation axis of the polygon mirror; providing a second mold contoured to form a second side of the frame facing in another of the two opposite directions parallel to the rotation axis; assembling the first mold and the second mold together with the insert into a mold; injecting a plastic material into the mold to perform injection molding to form the frame; moving the first mold or the second mold in a direction parallel to the rotation axis to remove the frame, as molded, from the first mold and the second mold; and moving the insert in a direction parallel to the optical axis to remove the insert from the frame as molded.

### BRIEF DESCRIPTION OF THE DRAWINGS

The above and other aspects, their advantages and further features will become more apparent by describing in detail illustrative, non-limiting embodiments thereof with reference to the accompanying drawings.

FIG. 1 is a perspective view of a scanning optical device as viewed from one side of a frame, i.e., showing a side of the frame facing in a direction opposite to a first direction.

FIG. 2 is a perspective view showing a structure around coupling lenses held by holders.

FIG. 3 is a perspective view of the scanning optical device as viewed from the other side of the frame, i.e., showing another side of the frame facing in the first direction.

FIG. 4 is a section view taken along line IV-IV of FIG. 1.

FIG. 5 is a section view taken along line V-V of FIG. 1.

FIG. 6A is a perspective view of a first laser holder.

FIG. 6B is a rear view of the first laser holder as viewed from a rear side thereof, i.e., showing a side of the first laser holder facing in a direction opposite to a third direction.

FIG. 6C is a partially cutaway side view of the first laser holder.

FIG. 7 is an exploded perspective view illustrating the frame and the laser holders.

FIG. 8A is a rear view of the frame as viewed from the rear side thereof, i.e., showing a side of the frame facing in the direction opposite to the third direction.

FIG. 8B is a section view showing apertures formed in the diaphragm which serve as aperture stops.

FIG. 9A is a perspective view of the first lens holder.

FIG. 9B is a perspective view showing relative locations of a first semiconductor laser and the first lens holder, and an optical axis of the first semiconductor laser.

FIG. 10A, FIG. 10B, FIG. 10C and FIG. 10D are diagrams showing process steps of attaching coupling lenses to the frame.

FIG. 11 is a perspective view of the frame and an insert for use in a process of injection molding of the frame.

FIG. 12 is a section view for illustrating the frame as formed in the process of injection molding using molds and the insert.

FIG. 13 is a perspective view showing a structure around coupling lenses held by holders in a scanning optical device according to a modified example.

FIG. 14A is a perspective view of a lens holder as viewed from a front side thereof, i.e., showing a side of the lens holder facing in the third direction.

FIG. 14B is a perspective view of the lens holder as viewed from a rear side thereof, i.e., showing another side of the lens holder facing in the direction opposite to the third direction.

FIG. 15 is a diagram showing relative locations of second bosses and first locating surfaces.

FIG. 16 is a diagram showing relative locations of first bosses and second locating surfaces.

FIG. 17A, FIG. 17B and FIG. 17C are diagrams showing process steps of attaching second coupling lenses to the frame.

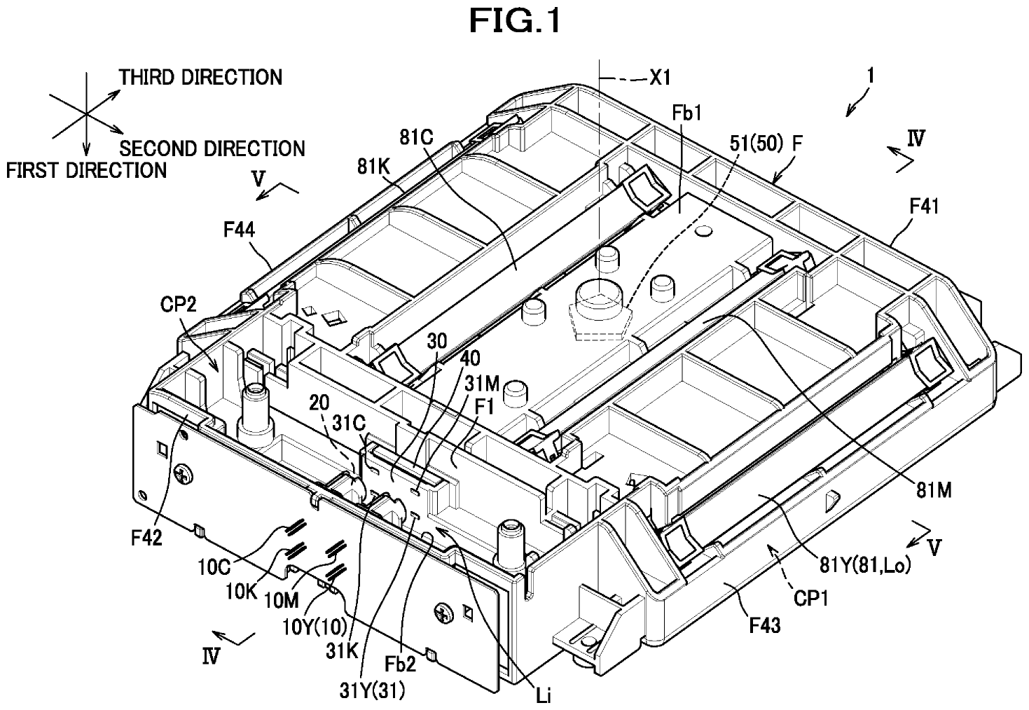

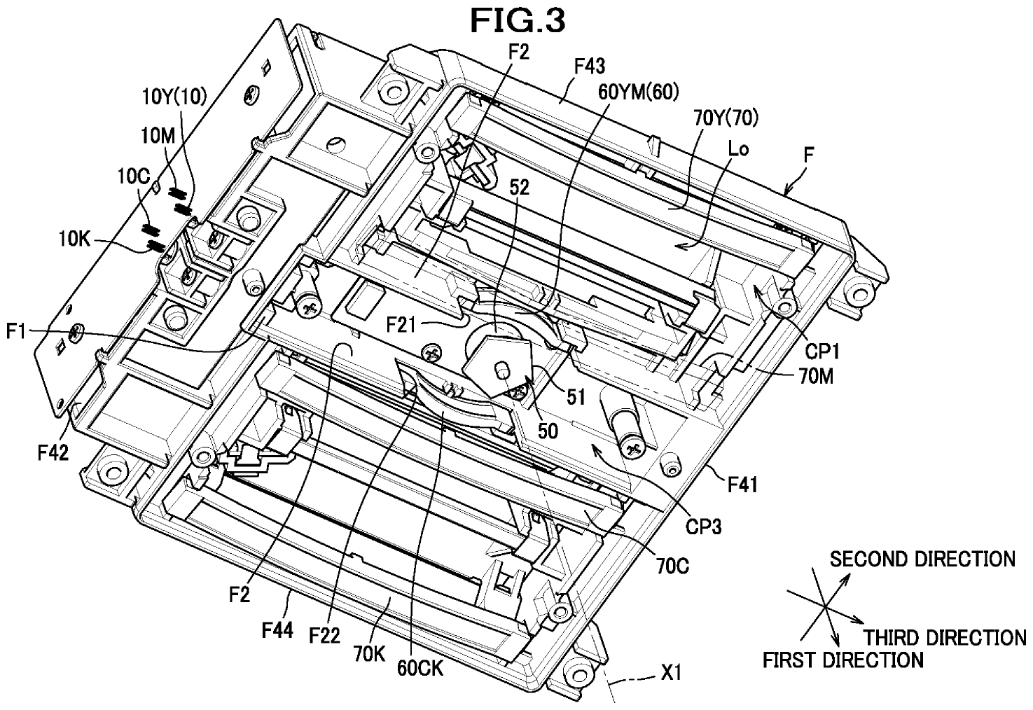

As shown in FIGS. 1 to 3, a scanning optical device 1 comprises a frame F, an illumination optical system Li, a deflector 50, and a scanning optical system Lo. The scanning optical device 1 is a device to be incorporated in an electrophotographic image forming apparatus. In the following description, the terms “first direction”, “second direction”, and “third direction” are used to refer to directions with respect to a frame F of the scanning optical device 1 as shown in FIG. 3. The first direction refers to a direction parallel to a rotation axis X1 of a polygon mirror 51. The second direction is a perpendicular direction perpendicular to the rotation axis X1 and to an optical axis of a first semiconductor laser 10Y as will be described later. The third direction is a direction parallel to the optical axis. The third direction corresponds to a direction in which light emitted by the semiconductor laser 10Y travels toward the polygon mirror 51. The third direction is a direction perpendicular to the first direction and to the second direction. The polygon mirror 51 and two first scan lenses 60 are arranged side by side along the second direction as shown in FIG. 3. The third direction is a direction parallel to a main scanning direction in the scanning optical system Lo. The first direction corresponds to a sub-scanning direction, in the illumination optical system Li, perpendicular to the main scanning direction.

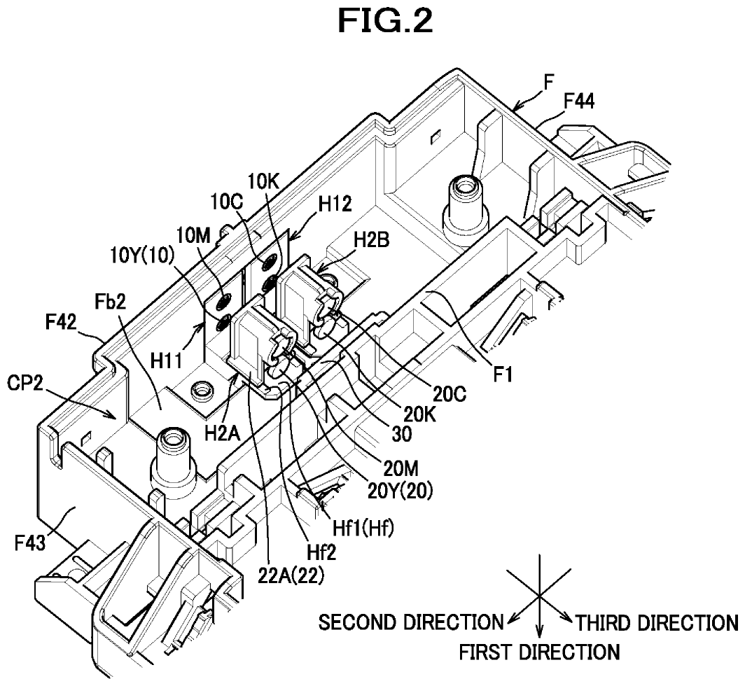

As shown in FIG. 2, the illumination optical system Li comprises four semiconductor lasers 10, four coupling lenses 20, a diaphragm 30, and a condenser lens 40 (see FIG. 1).

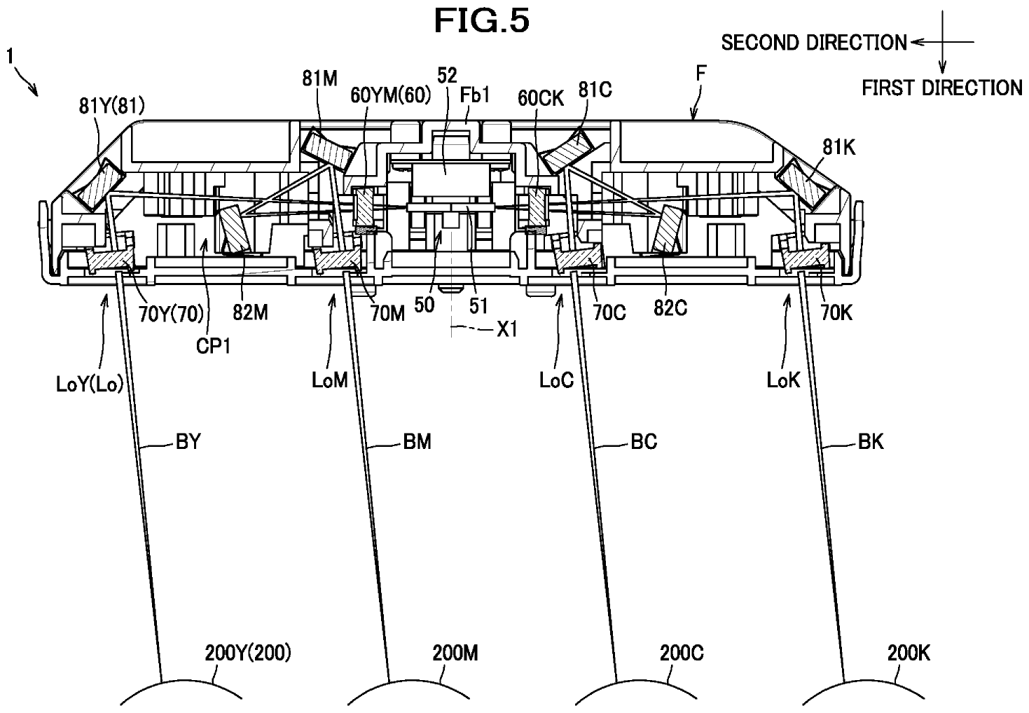

The semiconductor lasers 10 are devices configured to emit light. The four semiconductor lasers 10 correspond to four photoconductor drums 200 (see FIG. 5) to be scanned with and exposed to light by the scanning optical device 1. Toner images to be formed on the photoconductor drums 200 are different from one another in color.

In the present embodiment, the photoconductor drums 200 for a first color “yellow (Y)”, a second color “magenta (M)”, a third color “cyan (C)”, and a fourth color “black (B)” are arranged in this order in a direction opposite to the second direction. In the following description, parts provided for the four colors will be referred to by prefixing “first”, “second”, “third”, and “fourth” to their common name and suffixing “Y”, “M”, “C”, and “K” to their reference characters for making the parts discriminable from on another (e.g. first photoconductor drum 200Y, second photoconductor drum 200M, third photoconductor drum 200C, and fourth photoconductor drum 200K).

The first semiconductor laser 10Y is located apart from the second semiconductor laser 10M in the first direction. The third semiconductor laser 10C is located apart from the second semiconductor laser 10M in a direction opposite to the second direction. The fourth semiconductor laser 10K is located apart from the third semiconductor laser 10C in the first direction, and apart from the first semiconductor laser 10Y in the direction opposite to the second direction.

The coupling lenses 20 are lenses configured to convert light emitted by the semiconductor lasers 10 into light beams. The coupling lenses 20Y 20M, 20C, and 20K for respective colors are located in positions corresponding to the positions of the semiconductor lasers 10Y, 10M, 10C, and 10K and aligned with the corresponding semiconductor lasers 10Y, 10M, 10C, and 10K. Each coupling lens 20 is a plastic lens having an incident-side surface and an exit-side surface. Each of the incident-side surface and the exit-side surface is an axisymmetric optical surface. Each coupling lens 20 has a refractive power and a diffractive power.

As shown in FIG. 1, the diaphragm 30 is a portion having aperture stops 31 each positioned to allow a light beam received from the corresponding coupling lens 20 to pass therethrough. The diaphragm 30 is formed integrally with the frame F in one piece. The diaphragm 30 is positioned between the coupling lenses 20 and the condenser lens 40. The diaphragm 30 has a plurality of aperture stops 31 the number of which coincide with the number of the semiconductor lasers 10. In this embodiment, the diaphragm 30 has four aperture stops 31Y, 31M, 31C, and 31K corresponding to the four semiconductor lasers 10Y, 10M, 10C, and 10K.

The condenser lens 40 is a lens configured to condense a light beam received from each coupling lens 20, in the sub-scanning direction. The condenser lens 40 is located behind the coupling lenses 20 as viewed from the diaphragm 30. That is, the condenser lens 40 and each coupling lens 20 are located on opposite sides of the diaphragm 30. In other words, the condenser lens 40 is located between the aperture stops 31 and the polygon mirror 51.

As shown in FIG. 3, the deflector 50 includes a polygon mirror 51 and a motor 52. The polygon mirror 51 is a mirror configured to deflect a light beam received from the condenser lens 40, in the main scanning direction. The polygon mirror 51 has five reflectors provided in locations equidistant from the rotation axis X1. The motor 52 is a motor for rotating the polygon mirror 51. The motor 52 is fixed to the frame F.

The scanning optical system Lo is an optical system configured to cause a light beam being deflected by the deflector to be focused onto a surface (image plane) of each photoconductor drum 200 to form an image thereon. The scanning optical system Lo is fixed to the frame F. As shown in FIG. 5, the scanning optical system Lo includes a first scanning optical system LoY for yellow, a second scanning optical system LoM for magenta, a third scanning optical system LoC for cyan, and a fourth scanning optical system LoK for black.

The first scanning optical system LoY and the second scanning optical system LoM are located in positions distanced from the polygon mirror 51 in the second direction. The third scanning optical system LoC and the fourth scanning optical system LoK are located in positions distanced from the polygon mirror 51 in a direction opposite to the second direction. A light beam being deflected by the polygon mirror 51 in the main scanning direction enters each of the scanning optical systems LoY, LoM, LoC, and LoK.

The first scanning optical system LoY includes a first scan lens 60YM, a second scan lens 70Y, and a reflecting mirror 81Y.

The first scan lens 60YM is a lens configured to cause a light beam being deflected by the deflector 50 to be refracted in the main scanning direction, for the light beam to be focused onto an image plane to form an image. In addition, the first scan lens 60YM has an fθ characteristic to cause the light beam being deflected by the deflector 50 in a uniform angular velocity to be made into a light beam with which the image plane is scanned in a uniform linear velocity. The first scan lens 60YM is a scan lens located closest to the polygon mirror 51 among optics in the first scanning optical system LoY.

The reflecting mirror 81Y is a mirror configured to reflect a light beam BY received from the first scan lens 60Y, toward the image plane.

The second scan lens 70Y is a lens configured to cause the light beam BY reflected from the reflecting mirror 81Y to be refracted in the sub-scanning direction, for the light beam to be focused onto the image plane to form an image. The second scan lens 70Y is located in a position closer to a first side of an inside space of the frame F distanced from the polygon mirror 51 in the first direction than to a second side (a side opposite to the first side) of the inside space of the frame F distanced from the polygon mirror 51 in a direction opposite to the first direction. That is, the second scan lens 70Y is located closer, than the polygon mirror 51, to the first side of the inside space of the frame F. The second scan lens 70Y is a scan lens located closest to the image plane among the optics in the first scanning optical system LoY.

The second scanning optical system LoM includes a first scan lens 60YM, a second scan lens 70M, a reflecting mirror 81M, and a mirror 82M.

One and the same first scan lens 60YM as used in the first scanning optical system LoY is also used in the second scanning optical system LoM. The second scan lens 70M and the reflecting mirror 81M have the same functions as those of the second san lens 70Y and the reflecting mirror 81Y. The mirror 82 is a mirror that reflects a light beam BM received from the first scan lens 60YM, toward the reflecting mirror 81M.

The third scanning optical system LoC has an arrangement approximately line-symmetrical to the second scanning optical system LoM with respect to the rotation axis X1 of the polygon mirror 51. To be more specific, the third scanning optical system LoC includes a first scan lens 60CK, a second scan lens 70C, a reflecting mirror 81C, and a mirror 82C which respectively have the same functions as those of the corresponding components of the second scanning optical system LoM.

The fourth scanning optical system LoK has an arrangement approximately line-symmetrical to the first scanning optical system LoY with respect to the rotation axis X1 of the polygon mirror 51. To be more specific, the fourth scanning optical system LoK includes a first scan lens 60CK, a second scan lens 70K, and a reflecting mirror 81K which respectively have the same functions as those of the corresponding components of the first scanning optical system LoY.

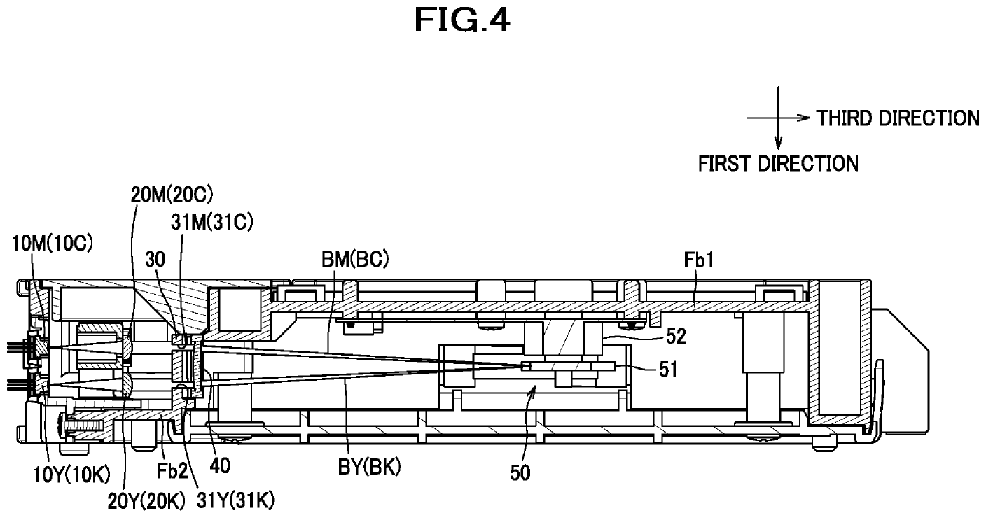

As shown in FIG. 4, pencils of light emitted from the semiconductor lasers 10Y, 10M, 10C, and 10K pass through the corresponding coupling lenses 20Y, 20M, 20C, and 20K, and are thereby converted into light beams BY, BM, BC, and BK, respectively. The light beams BY, BM, BC, and BK pass through the corresponding aperture stops 31Y, 31M, 31C, and 31K, then pass through the condenser lens 40, and strike the polygon mirror 51. The condenser lens 40 is a single lens arranged to allow all of the light beams BY, BM, BC, and BK to pass therethrough. The condenser lens 40 has an incident-side surface in a cylindrical shape and an exit-side surface in a flat shape.

As shown in FIG. 5, the polygon mirror 51 reflects and deflects the light beams BY, BM, BC, and BK toward the corresponding scanning optical systems LoY, LoM, LoC, and LoK. The light beam BY directed to the first scanning optical system LoY passes through the first scan lens 60YM, and is reflected off the reflecting mirror 81Y, by which the light beam BY is directed to pass through the second scan lens 70Y, and emitted from the frame F toward an image plane positioned at a distance from the frame F in the first direction. The light beam BY emitted through the second scan lens 70Y travels in a direction inclined at a predetermined acute angle with the first direction. The light beam BY is focused on the surface of the first photoconductor drum 200Y, which is thereby scanned with the light beam BY in the main scanning direction.

The light bean BM directed to the second scanning optical system LoM passes through the first scan lens 60YM, and is reflected off the mirror 82M and the reflecting mirror 81M, by which the light beam BY is directed to pass through the second scan lens 70M, and emitted from the frame F toward an image plane positioned at a distance from the frame in the first direction. The light beam BM emitted through the second scan lens 70M travels in a direction inclined at a predetermined acute angle with the first direction. The light beam BM is focused on the surface of the second photoconductor drum 200M, which is thereby scanned with the light beam BM in the main scanning direction.

Similarly, the light beams BC and BK are emitted by the third scanning optical system LoC and the fourth scanning optical system LoK, respectively, from the frame F toward corresponding image planes in directions inclined at predetermined acute angles with the first direction, and are focused on the surfaces of the third photoconductor drum 200C and the fourth photoconductor drum 200K, which are thereby scanned with the light beams BC and BK, respectively, in the main scanning direction.

The frame F is made of plastic, and formed by molding integrally in one piece. The frame F has a first recess CP1 shown in FIG. 3 and a second recess CP2 shown in FIG. 1. The first recess CP1 opens in the first direction. The second recess CP2 opens in a direction opposite to the first direction. As shown in FIG. 5, the deflector 50 and part of the scanning optical system Lo are located in the first recess CP1. Specifically, all the components, except the reflecting mirrors 81, of the scanning optical system Lo are located in the first recess CP1. As shown in FIG. 2, the coupling lenses 20, the diaphragm 30 and the condenser lens 40 (see FIG. 1) are located in the second recess CP2.

As shown in FIG. 1, the frame F comprises a first base wall Fb1 and a second base wall Fb2. The first base wall Fb1 forms a bottom of the first recess CP1. The second base wall Fb2 forms a bottom of the second recess CP2.

The first base wall Fb1 and the second base wall Fb2 are oriented nonparallel to, thus at an angle with respect to, the first direction. Specifically, the first base wall Fb1 and the second base wall Fb2 are walls which extend in the second direction and in the third direction, and have thicknesses as measured as dimensions in the first direction. To be more specific, the first base wall Fb1 and the second base wall Fb2 have flat surfaces perpendicular to the first direction.

The second base wall Fb2 is located in a position shifted in the first direction with respect to a position of the first base wall Fb1. As shown in FIG, 5, the deflector 50 and the aforementioned part of the scanning optical system Lo are attached directly or indirectly to the first base wall Fb1 from the first side (open side of the inside space) of the frame F. Thus, the deflector 50 and the aforementioned part of the scanning optical system Lo are located on, or apart in the first direction from, one side of the first base wall Fb1 facing in the first direction (i.e., in the first recess CP1 of the frame F). As shown in FIG. 2, the semiconductor laser 10, the coupling lenses 20, and the diaphragm 30 are located on, or apart in the direction opposite to the first direction from, one side of the second base wall Fb2 facing in the direction opposite to the first direction (i.e., in the second recess CP2 of the frame F). As shown in FIG. 1, the condenser lens 40 is also located on, or apart in the direction opposite to the first direction from, the aforementioned one side of the second base wall Fb2 facing in the direction opposite to the first direction (i.e., in the second recess CP2 of the frame F), and similarly, the reflecting mirrors 81 are located in positions shifted in the direction opposite to the first direction with respect to a position of the second base wall Fb2.

The reflecting mirrors 81 are located near the first base wall Fb1, and exposed through the second side of the frame F when the second side of the frame F is viewed in the first direction. In other words, the first base wall Fb1 has no part located over a side of each of the reflecting mirrors 81 facing in the direction opposite to the first direction. Accordingly, each reflecting mirror 81 is not covered with the first base wall Fb1, and exposed through the second side of the frame F when the second side of the frame F is viewed from the the first direction, so that each reflecting mirror 81 can be attached to the frame F in the first direction.

The frame F further comprises a first sidewall F41, a second sidewall F42, a third sidewall F43, and a fourth sidewall F44. The first, second, third and fourth sidewalls F41, F42, F43 and F44 constitute a frame having an approximately rectangular shape and surrounding the first and second recesses CP1 and CP2.

The first sidewall F41 is located behind the deflector 50 as viewed from the semiconductor laser 10. The first sidewall F41 protrudes from the first base wall Fb1 in the first direction.

The second sidewall F42 is located behind the deflector 50 as viewed from the first sidewall F41. To be more specific, the second sidewall F42 is located behind the coupling lenses 20 as viewed from the deflector 50. The second sidewall F42 protrudes from the second base wall Fb2 in the direction opposite to the first direction.

The third sidewall F43 is located behind the first scan lens 60YM as viewed from the deflector 50. The third sidewall F43 is connected to one of two ends (the end which faces in the second direction) of each of the first sidewall F41, the first base wall Fb1, the second base wall Fb2, and the second sidewall F42. One part of the third sidewall F43 protrudes from the first base wall Fb1 in the first direction, while the other part of the third sidewall F43 protrudes from the second base wall Fb2 in the direction opposite to the first direction.

The fourth sidewall F44 is located behind the first scan lens 60CK as viewed from the deflector 50. The fourth sidewall F44 is connected to the other end (the end which faces in the direction opposite to the second direction) of each of the first sidewall F41, the first base wall Fb1, the second base wall Fb2, and the second sidewall F42. One part of the fourth sidewall F44 protrudes from the first base wall Fb1 in the first direction, while the other part of the fourth sidewall F44 protrudes from the second base wall Fb2 in the direction opposite to the first direction.

As shown in FIG. 2, the scanning optical device 1 further comprises a first laser holder H11, a second laser holder H12, a first lens holder H2A, and a second lens holder H2B. The first laser holder H11 and the second laser holder H12 are examples of a first holder. The first lens holder H2A and the second lens holder H2B are examples of a second holder. The first laser holder H11, the second laser holder H12, the first lens holder H2A, and the second lens holder H2B are made of plastic. The first lens holder H2A and the second lens holder H2B are made of a material that allows light for curing a photo-curable resin to pass therethrough.

The first laser holder H11 is a member having a shape of a letter L in cross section and configured to hold the first semiconductor laser 10Y, the second semiconductor laser 10M, and the first coupling lens 20Y. The first coupling lens 20Y is fixed to the first laser holder H11 by a photo-curable resin. The first laser holder H11 is configured to allow the first coupling lens 20Y to be attached thereto in the first direction. The first laser holder H11 is fixed to the frame F. Specific configurations of the first laser holder H11 will be described later in detail. The second laser holder H12 is a member having a shape of a letter L in cross section and configured to hold the third semiconductor laser 10C, the fourth semiconductor laser 10K, and the fourth coupling lens 20K. The second laser holder H12 is different from the first laser holder H11 only in the parts to be held, and configured to have a structure equivalent to the first laser holder H11; therefore, a detailed description of the second laser holder H12 will be omitted.

The first lens holder H2A is a member configured to hold the second coupling lens 20M in such a position that the first coupling lens 20Y and the second coupling lens 20M are arranged in a line parallel to the first direction. The first lens holder H2A is fixed to the first laser holder H11 by a photo-curable resin. The first laser holder H11 and the first lens holder H2A are configured to allow the first lens holder H2A to be attached to the first laser holder H11 in the first direction. Specific configurations of the first lens holder H2A will be described later in detail. The second lens holder H2B is a member configured to hold the third coupling lens 20C in such a position that the third coupling lens 20C and the fourth coupling lens 20K are arranged in a line parallel to the first direction. The second lens holder H2B is different from the first lens holder H2A only in the parts to be held and parts to which they are fixed (the second lens holder H2B is fixed to the second laser holder H12, not to the first laser holder H11); therefore, a detailed description of the second lens holder H2B will be omitted.

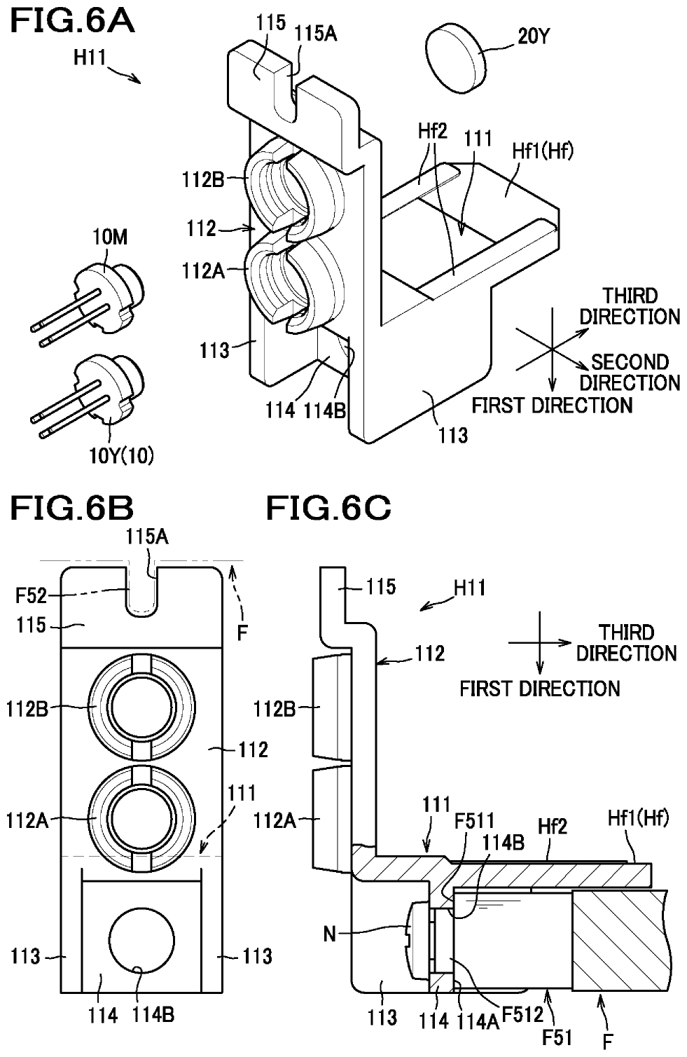

As shown in FIG. 6A, the first laser holder H11 includes a first portion 111, a second portion 112, two third portions 113, a first holder locating portion 114, and a second holder locating portion 115.

The first portion 111 is a portion in a shape of a plate having a thickness as measured in the first direction, a width in the second direction, and a length in the third direction (i.e., the dimension in the third direction is longer than the dimension in the second direction). The first portion 111 has a seating surface Hf. The seating surface Hf includes a first seating surface Hf1 and a second seating surface Hf2. The first seating surface Hf1 and the second seating surface Hf2 are flat surfaces perpendicular to the first direction. The first seating surface Hf1 and the second seating surface Hf2 face in the direction opposite to the first direction. As shown in FIG. 6C, the first portion 111 is spaced apart from the frame F with a gap provided therebetween in the first direction.

The first seating surface Hf1 is a seating surface on which the first coupling lens 20Y is fixed by a photo-curable resin. The first seating surface Hf1 is located in an area (facing in the direction opposite to the first direction) of the first portion 111 adjacent to a front-side edge thereof (i.e., an end of the first portion 111 facing in the third direction).

The second seating surface Hf2 is a seating surface on which the first lens holder H2A is fixed by a photo-curable resin. Two second seating surfaces Hf2 are provided in areas (facing in the direction opposite to the first direction) of the first portion 111 adjacent to side edges thereof facing in the second direction and in the direction opposite to the second direction. The second seating surfaces Hf2 are located in the areas apart from each other in the second direction, and shifted in the direction opposite to the third direction apart, i.e., retreated, from the front end of the first portion 111. Between the two second seating surfaces Hf2, the first seating surface Hf1 is located. The second seating surface Hf2 is located in a position shifted in the direction opposite to the first direction with respect to a position of the first seating surface Hf1.

As shown in FIG. 6A, the second portion 112 extends in the direction opposite to the first direction, from a rear end of the first portion 111 facing in the direction opposite to the third direction. The second portion 112 includes a first holder 112A configured to hold the first semiconductor laser 10Y and a second holder 112B configured to hold the second semiconductor laser 10M. Each of the first holder 112A and the second holder 112B comprises a through hole extending in the third direction (i.e., piercing from one side facing in the third direction to the other side facing in the direction opposite to the third direction), and a pair of ribs each having a semicylindrical shape and extending from the edge of the through hole in the direction opposite to the third direction. The semiconductor laser 10 is press-fitted into a gap between the ribs and held in place.

The third portions 113 extend from the first portion 111 in the first direction. Two third portions 113 are provided at ends of the first portion 111 facing in the second direction and in the direction opposite to the second direction. Each third portion 113 is formed in a location defined as extending from a position aligned with the rear end (the end facing in the direction opposite to the third direction) of the first portion 111, to a predetermined extent. The first portion 111 protrudes beyond the front ends (ends facing in the third direction) of the third portions 113 farther in the third direction.

As shown in FIGS. 6B and 6C, the first holder locating portion 114 is a portion serving to locate the first laser holder H11 in place relative to the frame F. The first holder locating portion 114 extends from the first portion 111 in the first direction. The first holder locating portion 114 is provided between the two third portions 113, and joined to the two third portions 113. The first holder locating portion 114 has a locating surface 114A with which the first laser holder H11 is positioned in the third direction, and a locating hole 114B with which the first laser holder H11 is positioned in the first direction and in the second direction.

As shown in FIG. 6C, the frame F includes a first boss F51 as an example of a first contact portion. The first boss F51 has a shape of a cylinder protruding in the direction opposite to the third direction. The first boss F51 has a first locating surface F511 as a contact surface that contacts the locating surface 114A of the first holder locating portion 114 which is fitted onto the first boss F51 in the third direction. The first boss F51 includes a protrusion F512 that is fitted in the locating hole 114B of the first holder locating portion 114. The first locating surface F511 is a surface with which the first laser holder H11 is positioned in the third direction as an example of a first predetermined direction. The protrusion F512 is an example of a first restraining portion with which the first laser holder H11 is positioned in the first direction as an example of a second predetermined direction and in the second direction. The protrusion F512 protrudes from the center of the first locating surface F511 in the direction opposite to the third direction.

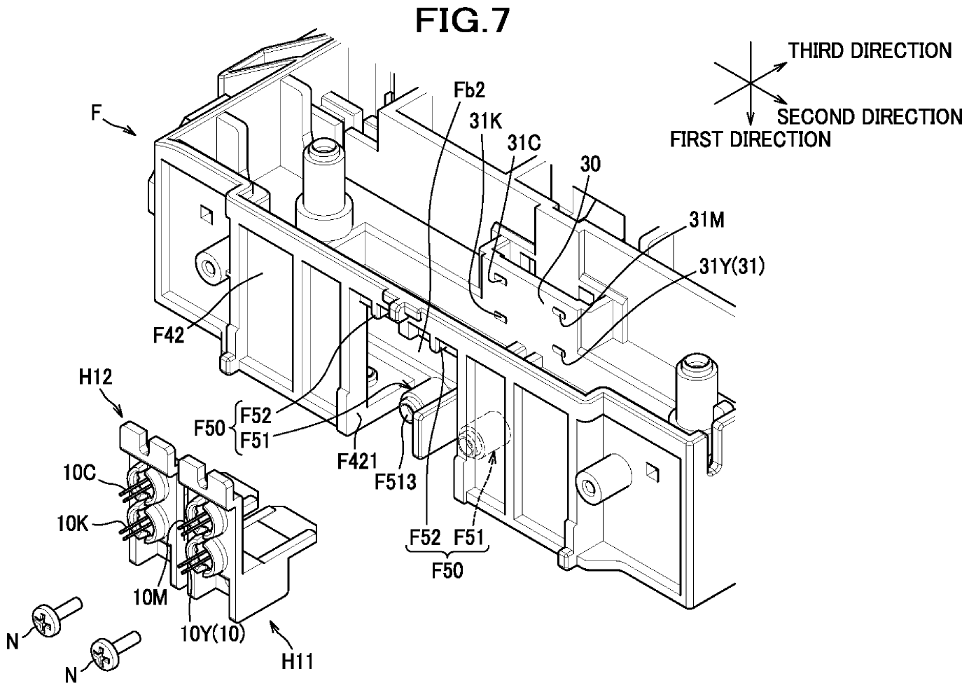

A hole F513 (see FIG. 7) configured to allow a screw N to be inserted therein is formed at a center of an end face of the protrusion F512. The first holder locating portion 114 is fixed to the frame F by the screw N inserted in the third direction. To be more specific, the first holder locating portion 114 is held between the head of the screw N and the first locating surface F511 of the first boss F51.

As shown in FIG. 6B, the second holder locating portion 115 is a portion that restrains the first laser holder H11 from rotating about the first boss F51. The second holder locating portion 115 which extends from an end of the second portion 112 facing in the direction opposite to the first direction, in the direction opposite to the third direction, is bent at a right angle in the direction opposite to the first direction, and extends in the direction opposite to the first direction. The second holder locating portion 115 has a slot 115A for restraining rotation of the first laser holder H11. The slot 115A pierces through the second holder locating portion 115, and opens in the direction opposite to the first direction.

The frame F includes a contact rib F52 as an example of a second contact portion. The contact rib F52 has a shape protruding in the first direction and in the direction opposite to the third direction (see FIG. 7). When the first laser holder H11 has been attached to the frame F, the contact rib F52 is located in the slot 115A of the second holder locating portion 115. The contact rib F52 contacts the slot 115A, specifically contacts the two opposed side edges of the slot 115A facing in opposite directions parallel to the second direction. The second holder locating portion 115 is spaced apart from the frame F in the first direction with clearance formed therebetween, as an allowance to accommodate thermal expansion.

The first holder locating portion 114, the first holder 112A, the second holder 112B, and the second holder locating portion 115 are arranged in this order in the direction opposite to the first direction. The first holder 112A and the second holder 112B are arranged between the first holder locating portion 114 and the second holder locating portion 115 in the direction of arrangement (i.e., the direction opposite to the first direction). The aforementioned first portion 111 is located between the first holder 112A and the first holder locating portion 114 arranged in the first direction.

Accordingly, when the first semiconductor laser 10Y and the second semiconductor laser 10M have been attached to the first laser holder H11, the first holder locating potion 114, the first semiconductor laser 10Y, the second semiconductor laser 10M, and the second holder locating portion 115 are arranged in this order in the direction of arrangement of the first semiconductor laser 10Y and the second semiconductor laser 10M. When the first semiconductor laser 10Y and the second semiconductor laser 10M have been attached to the first laser holder H11, the first semiconductor laser 10Y and the second semiconductor laser 10M are located between the first holder locating portion 114 and the second holder locating portion 115 in the direction of arrangement. When the first semiconductor laser 10Y and the second semiconductor laser 10M have been attached to the first laser holder H11, the first semiconductor laser 10Y is located between the second semiconductor laser 10M and the first holder locating portion 114 in the direction of arrangement. When the first semiconductor laser 10Y and the second semiconductor laser 10M have been attached to the first laser holder H11, the first portion 111 is located between the first semiconductor laser 10Y and the first holder locating portion 114 in the direction of arrangement.

As shown in FIG. 7, the frame F includes two locating portions (first and second locating portions) F50 each of which includes the first boss F51 and the contact rib F52 described above. The first locating portion F50 and the second locating portion F50 are arranged in the direction opposite to the second direction. The first locating portion F50 serves to locate the first laser holder H11 in place, and the second locating portion F50 serves to locate the second laser holder H12 in place. Each first boss F51 protrudes from the second base wall Fb2 of the frame F in the direction opposite to the third direction. The two first bosses F51 are arranged in a direction parallel to the second direction with a gap formed therebetween.

The second sidewall F42 of the frame F is located in a position distanced, farther than the positions of the first bosses F51, from the deflector 50 (see FIG. 1). In other words, the second sidewall F42 is located at one side of the frame F which is located in a position of which a distance from each locating portion F50 is shorter than a distance from the deflector 50, and the second sidewall F42 has an opening F421 through which the aperture stops 31Y, 31M, 31C, and 31K and the first bosses F51 are exposed to and accessible from outside.

The opening F421 pierces in the third direction and opens in the first direction. The contact ribs F52 are formed at an edge of the opening F421 opposite to a side thereof which opens in the first direction. The contact ribs F52 protrude from the edge of the opening F421 in the first direction.

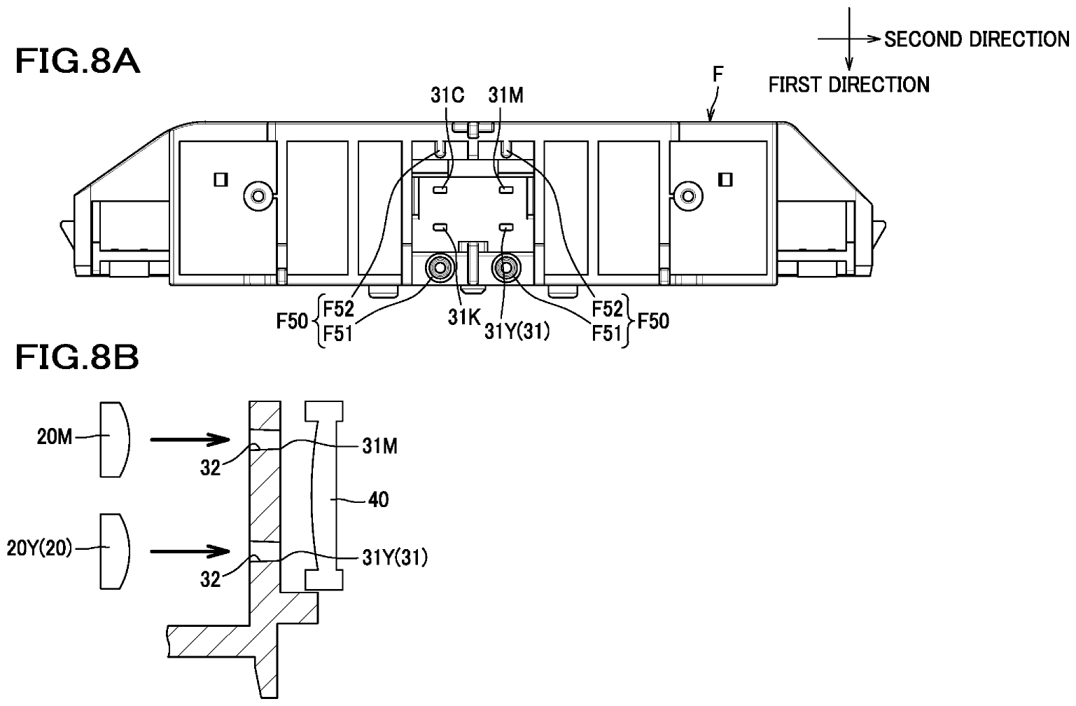

Accordingly, as shown in FIG. 8A, if no other member is attached to the frame F, the aperture stops 31Y, 31M, 31C, and 31K and the locating portions F50 are seen from outside of the frame F when viewed in the third direction. The aperture stops 31Y and 31M, and the first locating portion F50 are arranged in a straight line parallel to the first direction as viewed from the rear side of the frame F (when one side facing in the direction opposite to the third direction of the frame F is viewed). The aperture stops 31C and 31K, and the second locating portion F50 are arranged in a straight line parallel to the first direction as viewed from the rear side of the frame F.

The aperture stops 31Y and 31M are positioned between the first boss F51 and the contact rib F52 of the first locating portion F50 arranged in the direction parallel to the first direction. The aperture stops 31C and 31K are positioned between the first boss F51 and the contact rib F52 of the second locating portion F50 arranged in the direction parallel to the first direction.

As shown in FIG. 8B in an exaggerated manner, an aperture 32 formed to define each aperture stop 31 has a first open edge farther from the condenser lens 40 and a second open edge closer to the condenser lens 40, and the second open edge is smaller than the first open edge. It is to be understood that the aperture stop 31 is the second open edge (the open edge closer to the condenser lens 40, of the two) of the aperture 32.

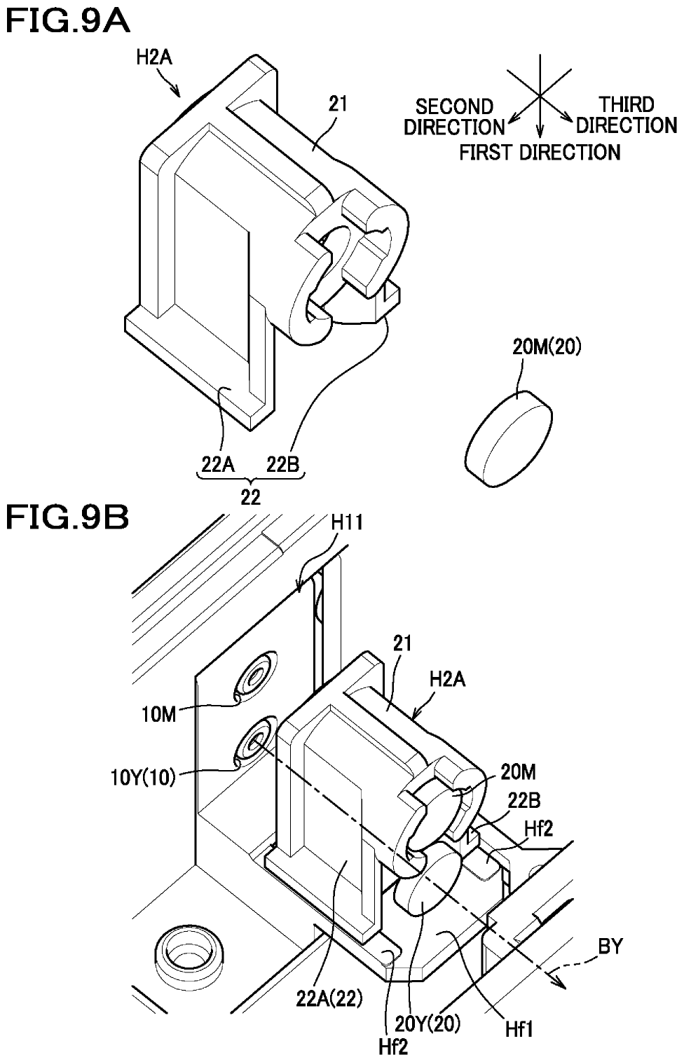

As shown in FIG. 9A, the first lens holder H2A comprises a lens attachment 21, and a leg 22. The lens attachment 21 is a portion to which the second coupling lens 20M is attached. The lens attachment 21 has a cylindrical shape, and an end thereof facing in the third direction is configured to allow the second coupling lens 20M to be fitted therein. The lens attachment 21 protrudes beyond the front end (an end facing in the third direction) of the leg 22 farther in the third direction.

The leg 22 comprises a first leg 22A and a second leg 22B. The first leg 22A and the second leg 22B extend from the lens attachment 21 in the first direction. Therefore, as shown in FIG. 9B, when the first lens holder H2A has been attached to the first laser holder H11, the leg 22 extends from the lens attachment 21 to the second seating surface Hf2. The first leg 22A is located in a position separate from the second leg 22B in the second direction. The first leg 22A and the second leg 22B are each fixed on the corresponding second seating surface Hf2 by a photo-curable resin.

The first leg 22A and the second leg 22B of the first lens holder H2A are located astride a path of light emitted from the first semiconductor laser 10Y. Therefore, the light traveling from the first semiconductor laser 10Y to the first coupling lens 20Y passes through a gap formed between the first leg 22A and the second leg 22B.

Next, a description will be given of a method for making a scanning optical device 1. A method of attaching coupling lenses 20 to a frame F will be discussed in the first place, and a method of forming the frame F will be discussed in the last place.

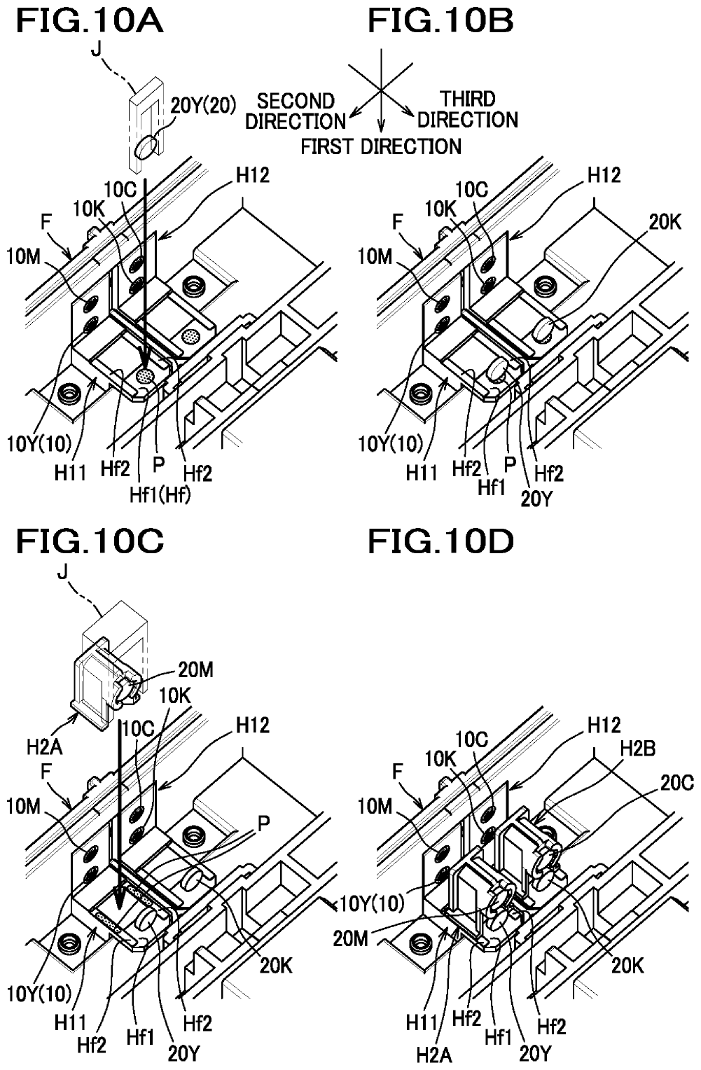

As shown in FIG. 7, to attach coupling lenses 20 to a frame F, first, laser holders H11 and H12 in which the semiconductor lasers 10 are held are attached to the frame F by screws N. Thereafter, a first bonding process as shown in FIGS. 10A and 10B is executed, and then a second bonding process as shown in FIGS. 10C and 10D is executed.

As shown in FIG. 10A, in the first bonding process, first, the first coupling lens 20Y is held by using a jig J that holds the first coupling lens 20Y at two ends thereof facing in opposite directions parallel to the second direction. Subsequently, a photo-curable resin P which has not been cured yet is placed between the first coupling lens 20Y and the first seating surface Hf1 of the first laser holder H11. In an example illustrated in FIG. 10A, the photo-curable resin P is applied on the first seating surface Hf1 of the first laser holder H11, before the first coupling lens 20Y is brought close to the first seating surface Hf1.

Next, the jig J is moved in the first direction, to move the first coupling lens 20Y in the first direction through an open side of the frame F which opens in the direction opposite to the first direction, thereby bringing the first coupling lens 20Y close to the first seating surface Hf1 in the first direction, until the photo-curable resin P is sandwiched between the first coupling lens 20Y and the first seating surface Hf1. Thereafter, a position of the first coupling lens 20Y relative to the first semiconductor laser 10Y is adjusted by moving the jig J in the first direction, the second direction, and/or the third direction.

After completion of adjustment of the position of the first coupling lens 20Y, light is applied to the photo-curable resin P to bond and fix the first coupling lens 20Y to the first seating surface Hf1 of the first laser holder H11, as shown in FIG. 10B. The fourth coupling lens 20K is bonded and fixed to the second laser holder H12 by the same method as the above-described method of attaching the first coupling lens 20Y to the first laser holder H11. In the present embodiment, the photo-curable resin P is an ultraviolet-curable resin, and light applied to cure the resin is ultraviolet light.

As shown in FIG. 10C, in the second bonding process, first, the first lens holder H2A in which the second coupling lens 20M is held at two ends thereof facing in opposite directions parallel to the second direction by a jig J. Next, a photo-curable resin P which has not been cured yet is placed between the first lens holder H2A and the second seating surface Hf2 of the first laser holder H11. In an example illustrated in FIG. 10C, the photo-curable resin P is applied on the second seating surface Hf2 of the first laser holder H11, before the first lens holder H2A is brought close to the second seating surface Hf2.

Next, the jig J is moved in the first direction, to move the first lens holder H2A in the first direction through an open side of the frame F which opens in the direction opposite to the first direction, thereby bringing the first lens holder H2A close to the second seating surface Hf2 in the first direction, until the photo-curable resin P is sandwiched between the first lens holder H2A and the second seating surface Hf2. Thereafter, a position of the second coupling lens 20M relative to the second semiconductor laser 10M is adjusted by moving the jig J in the first direction, the second direction, and/or the third direction.

After completion of adjustment of the position of the second coupling lens 20M, light is applied to the photo-curable resin P to bond and fix the first lens holder H2A to the second seating surface Hf2 of the first laser holder H11, as shown in FIG. 10D. In this operation, light for curing a photo-curable resin P can be applied through the transparent first lens holder H2A to the photo-curable resin P, so that the whole photo-curable resin P can be cured without fail. The third coupling lens 20C is fixed via the second lens holder H2B to the second laser holder H12 by the same method as the above-described method of attaching the second coupling lens 20M via the first lens holder H2A to the first laser holder H11.

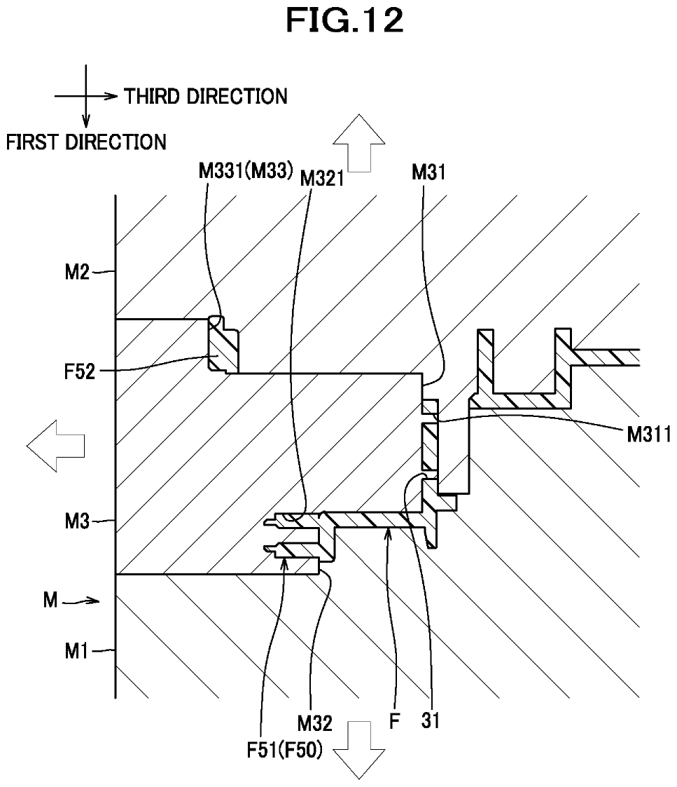

As shown in FIG. 12, the method of forming a frame F uses a mold M for injection molding, which includes a first mold M1, a second mold M2, and an insert M3, to perform injection molding the frame F so that the frame F with the aperture stops 31 and the locating portions F50 formed integrally therein is made into one piece. The first mold M1 is a mold contoured to form a first side of the frame F facing in the first direction. The second mold M2 is a mold contoured to form a second side of the frame F opposite to the first side. At least one of the first mold M1 and the second mold M2 is moveable in directions parallel to the first direction.

The insert M3 is a mold part contoured to form the locating portions F50 and the aperture stops 31 of the frame F. The insert M3 is movable in directions parallel to the third direction.

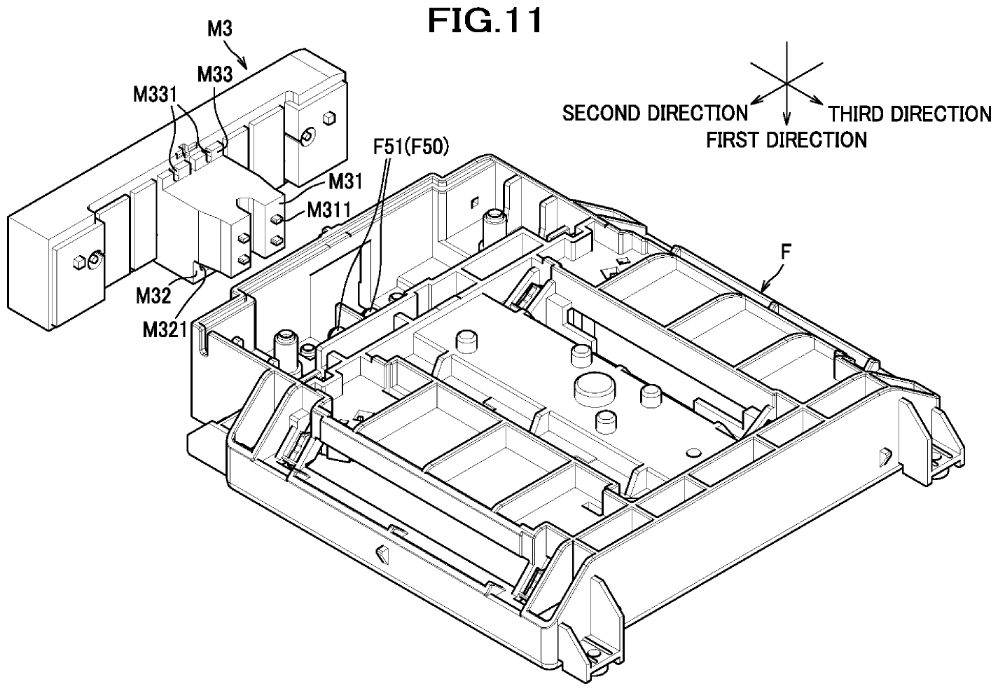

As shown in FIG. 11, the insert M3 is an integral part having a first mold surface M31, two second mold surfaces M32, M33 provided integrally therein. The first mold surface M31 is a surface for forming four aperture stops 31. The first mold surface M31 has four protrusions M311 for forming four aperture stops 31, to be specific, four apertures 32 (see FIG. 8). Each protrusion M311 is configured to have a distal end of which an area projected in the third direction is smaller than a cross-sectional area of a section thereof closer to the first mold surface M31. Accordingly, an open edge of the aperture 32 closer to the condenser lens 40 can be made smaller than the other open edge thereof. To be more specific, the aperture 32 is formed with a first open edge farther from the condenser lens 40 and a second open edge closer to the condenser lens 40 which is smaller than the first open edge, such that the aperture 32 tapers down from the first open edge toward the second open edge. Accordingly, the insert M3 can be moved easily in the direction opposite to the third direction away from the frame F.

The second mold surface M32 is a surface for forming the two first bosses F51 of the locating portions F50. The second mold surface M32 has two recesses M321 contoured to form the two first bosses F51. The second mold surface M33 is a surface for forming the two contact ribs F52 (see FIG. 8). The second mold surface M33 has two recesses M331 contoured to form the two contact ribs F52.

The method of forming a frame F comprises a first step, a second step, and a third step.

As shown in FIG. 12, in the first step, a plastic material is injected into a mold M assembled from the first mold M1, the second mold M2 and the insert M3, to form a frame F.

In the second step, which is performed after the frame F is formed, at least one of the first mold M1 and the second mold M2 is moved in a direction parallel to the first direction, and separated from the frame F. In the third step, which is performed after the frame F is formed, the insert M3 is moved in the direction opposite to the third direction and separated from the frame F. By going through the steps as described above, the aperture stops 31 and the locating portions F50 can be formed integrally in the frame F.

In the present embodiment as described above, the following advantageous effects can be achieved.

The first coupling lens 20Y can be carried in the first direction toward and attached to the first seating surface Hf1, and then the first lens holder H2A holding the second coupling lens 20M can be carried in the same direction (i.e., the first direction) toward and attached to the second seating surface Hf2. Thus, a plurality of coupling lenses 20 can be attached on one and the same side so that complicated work can be obviated in the process of making the scanning optical device.

Since the leg 22 extending from the lens attachment 21 is provided in the first lens holder H2A, an undesirable collision of the lens attachment 21 with the first coupling lens 20Y can be made less likely to occur.

Since the two legs 22A, 22B of the first lens holder H2A are fixed to the first laser holder H11, the second coupling lens 20M can be held stably by the first lens holder H2A.

When the first lens holder H2A is fixed to the first laser holder H11, light for curing the photo-curable resin can be applied through the transparent first lens holder H2A to a photo-curable resin P to cure the photo-curable resin P; therefore, the first lens holder H2A can be fixed to the first laser holder H11 with ease.

Since the second portion 112 which holds the first semiconductor laser 10Y and the seating surface Hf on which the first coupling lens 20Y is fixed can be integrally formed of a single part, the first coupling lens 20Y can be located in place relative to the first semiconductor laser 10Y with increased precision.

Since both of the first laser holder H11 and the first lens holder H2A are made of plastic, the first laser holder H11 and the first lens holder H2A can be formed to have the same linear expansivity; therefore, undesirable deviation in relative positions of the first coupling lens 20Y and the second coupling lens 20M due to thermal expansion of the first laser holder H11 and the first lens holder H2A can be minimized. Furthermore, variations of refractive powers and diffractive powers of the first coupling lens 20Y and the second coupling lens 20M due to change in temperature can be compensated for by making use of the linear expansivities of the first laser holder H11 and the first lens holder H2.

Since the holder locating portions 114, 115 and the semiconductor lasers 10Y, 10M are aligned in the direction of arrangement of the semiconductor lasers 10Y, 10M, the tolerance management can be facilitated.

Since the first semiconductor laser 10Y and the second semiconductor laser 10M are arranged in the sub-scanning direction, the first semiconductor laser 10Y for exposure at a first image plane and the second semiconductor laser 10M for exposure at a second image plane different from the first image plane can be attached to one and the same laser holder, i.e., the first laser holder H11.

Since the frame F comprises the first boss F51 that contacts a side of the first holder locating portion 114 facing in a direction parallel to the third direction, the first laser holder H11 can be located in place relative to the frame F in the third direction.

Since the frame F comprises the contact rib F52 that contacts a side of the second holder locating portion 115 facing in a direction parallel to the second direction, rotation or angular displacement of the first laser holder H11 relative to the frame F can be restrained.

Since the first coupling lens 20Y is fixed on the seating surface Hf by a photo-curable resin P, the first coupling lens 20Y can be located in place and fixed on the seating surface Hf by applying light to the photo-curable resin P after adjustment in position of the first coupling lens 20Y relative to the first semiconductor laser 10Y.

Since the first portion 111 is spaced apart from the frame F with a gap provided therebetween in the first direction, the tolerance of the frame F and the first laser holder H11 would not affect the seating surface Hf.

Since the first laser holder H11 is made of plastic, the first laser holder H11 can be shaped with increased flexibility, and the expansivity can be specified from a wide range of values.

Since the aperture stops 31 and the locating portions F50 are formed by using one and the same insert M3, the positioning accuracy for the aperture stops 31 and the locating portions F50 can be increased.

Since the aperture 32 formed to define each aperture stop 31 in the diaphragm 30 has a first open edge farther from the condenser lens 40 and a second open edge closer to the condenser lens 40 which is smaller than the first open edge, the size of the aperture stop 31 as defined by the open edge closer to the condenser lens 40 can be made to conform to dimensional requirements.

Since the second sidewall F42 is provided, the rigidity of the frame F can be increased by the second sidewall F42. Since the second sidewall is provided with the opening F421, the aperture stops 31 and the locating portions F50 can be formed by using one and the same insert M3 which can be inserted through the opening F421.

While the invention has been described in conjunction with various example structures outlined above and illustrated in the figures, various alternatives, modifications, variations, improvements, and/or substantial equivalents, whether known or that may be presently unforeseen, may become apparent to those having at least ordinary skill in the art. Accordingly, the example embodiments of the disclosure, as set forth above, are intended to be illustrative of the invention, and not limiting the invention. Various changes may be made without departing from the spirit and scope of the disclosure. Therefore, the disclosure is intended to embrace all known or later developed alternatives, modifications, variations, improvements, and/or substantial equivalents. Some specific examples of potential alternatives, modifications, or variations in the described invention are provided below.

In the above-described embodiment, the first holder is configured as a laser holder; however, the first holder may alternatively be formed, for example, as part of the frame of the scanning optical device. In this example, a semiconductor laser may be held by a laser holder attached to the frame, or may be held by the frame.

In the above-described embodiment, the second holder is fixed on the seating surface of the first holder by a photo-curable resin; however, the second holder may be fixed, for example, to any portion of the first holder, other than the seating surface by a photo-curable resin. The number of legs of the second holder may be one, three or more.

In the above-described embodiment, the coupling lenses, and other components are fixed on seating surfaces by a photo-curable resin; however, the coupling lenses or other components may be fixed on the corresponding seating surfaces, for example, by bonding using an adhesive other than a photo-curable resin.

In the above-described embodiment, the first lens holder and the second lens holder are made of transparent plastic material; however, any transparent material other than plastic can be used as long as light for curing a photo-curable resin can pass therethrough. Alternatively, any structure that allows light to reach positions between the first lens holder and the second seating surface, and between the second lens holder and the second seating surface may be provided, instead.

In the above-described embodiment, the locating portion is configured to have a protuberant shape (i.e., as a protrusion); however, the locating portion may have a shape recessed in a direction parallel to an optical axis.

In the above-described embodiment, the first contact portion is configured as a boss, and the first holder locating portion has a hole in which the boss is fitted; however, an alternative configuration may be implemented by the first holder locating portion configured as a boss, and the first contact portion having a hole in which the boss is fitted.

The semiconductor laser 10 may be configured to include a plurality of illumination points. Light emitted from each illumination point is converted by a single common coupling lens 20 into a light beam. Thus-produced light beams corresponding to the illumination points are focused on a surface of each photoconductor drum 200 by a corresponding scanning optical system Lo. Consequently, the light beams BY, BM, BC, and BK as mentioned in connection with the above-described embodiment include a plurality of beams derived from the plurality of illumination points, respectively.

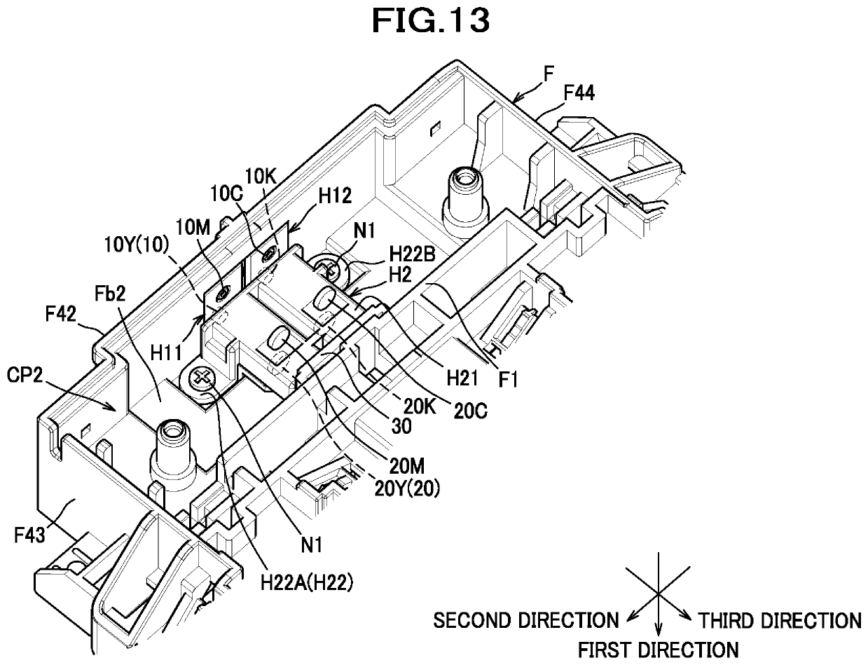

The following description of a modified example of the above-described embodiment, given with reference mainly to FIGS. 13 to 17, will focus on features distinctive from those of the above-described embodiment. In the above-described embodiment, the first lens holder H2A holding the second coupling lens 20M and the second lens holder H2B holding the third coupling lens 20C are taken as examples of the second holder. In the modified example as will be described below, the second holder is configured as a single lens holder H2.

As shown in FIG. 13, the scanning optical device 1 comprises a first laser holder H11, a second laser holder H12, and a lens holder H2. The first laser holder H11 and the second laser holder H12 are examples of the first holder. The lens holder H2 is an example of the second holder. The first laser holder H11, the second laser holder H12, and the lens holder H2 are made of plastic.

The lens holder H2 is a member that holds the second coupling lens 20M and the third coupling lens 20C. Specifically, the lens holder H2 is configured to hold the second coupling lens 20M in such a position that the second coupling lens 20M and the first coupling lens 20Y are arranged in a line parallel to the first direction. The lens holder H2 is also configured to hold the third coupling lens 20C in such a position that the third coupling lens 20C and the fourth coupling lens 20K are arranged in a line parallel to the first direction.

The lens holder H2 is fixed to the second base wall Fb2 of the frame F by screws N1. The lens holder H2 is configured to be attachable by being carried in the first direction and attached to a side of the second base wall Fb2 facing in the direction opposite to the first direction. Specific configurations of the lens holder H2 will be described below in detail.

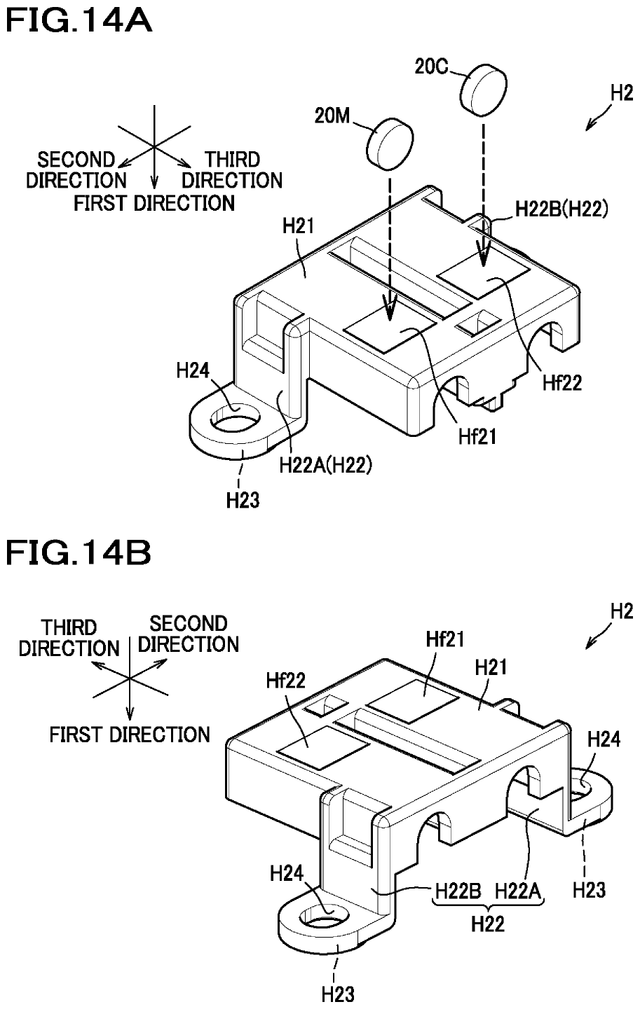

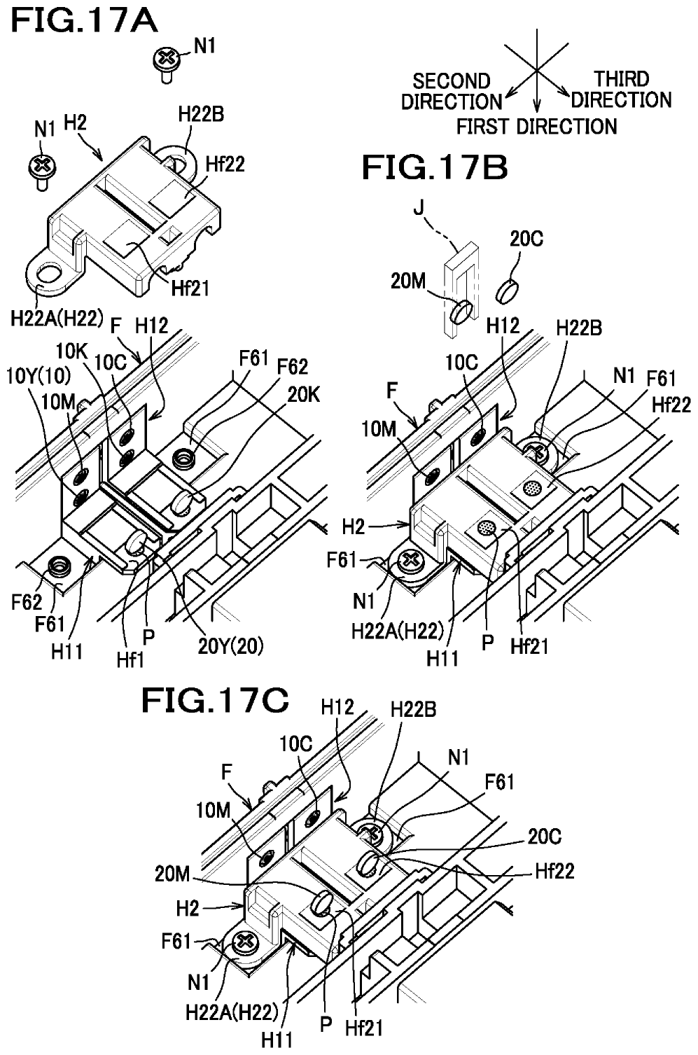

As shown in FIG. 14, the lens holder H2 comprises a base H21 and a leg H22. The base H21 has two second seating surfaces Hf21, Hf22. The two second seating surfaces Hf21, Hf22 are arranged in a line parallel to the second direction, apart from each other with a gap provided therebetween. Specifically, the second seating surface Hf21 is located apart from the second seating surface Hf22 in the second direction. The second seating surface Hf21 is a seating surface on which the second coupling lens 20M is fixed by a photo-curable resin. The second seating surface Hf22 is a seating surface on which the third coupling lens 20C is fixed by a photo-curable resin. The two second seating surfaces Hf21, Hf22 are flat surfaces perpendicular to the first direction. The base H21 extends beyond the front side (a side facing in the third direction) of the leg H22 in the third direction. The base H21 of the lens holder H2 carried in the first direction is placed over the first coupling lens 20Y and the fourth coupling lens 20K fixed on the corresponding seating surfaces Hf1 (facing in the direction opposite to the first direction) of the first laser holder H11 and the second laser holder H12 (see FIGS. 13 and 17A).

The leg H22 comprises a first leg H22A and a second leg H22B. The first leg H22A is located in a position separate from the second leg H22B in the second direction. The first leg H22A and the second leg H22B extend from the base H21 in the first direction. In other words, the first leg H22A and the second leg H22B extend, on the sides of the base 21 facing in the second direction and in the direction opposite to the second direction, from the edges of the surface of the base 21 facing in the direction opposite to the first direction, beyond the edges of the surface of the base H21 facing in the first direction (in a direction opposite to the direction in which the second seating surfaces Hf21, Hf22 face). The first leg H22A and the second leg H22B extending from the base H21 in the first direction are bent and further extend outward in opposite directions parallel to the second direction away from each other.

The two second seating surfaces Hf21, Hf22 are located between the first leg H22A and the second leg H22B located separate from each other in directions parallel to the second direction. As shown in FIG. 13, the first leg H22A and the second leg H22B are fixed to the second base wall Fb2 of the frame F by screws N1, respectively.

The first leg H22A and the second leg H22B of the lens holder H2 are located astride a path of light emitted from the first semiconductor laser 10Y and a path of light emitted from the fourth semiconductor laser 10K. Therefore, the light traveling from the first semiconductor laser 10Y to the first coupling lens 20Y and the light traveling from the fourth semiconductor laser 10K to the fourth coupling lens 20K pass through a gap formed between the first leg H22A and the second leg H22B.

Each of the first leg H22A and the second leg H22B has a locating surface H23 with which the lens holder H2 is positioned in the first direction, and a locating hole H24 with which the lens holder H2 is positioned in the third direction.

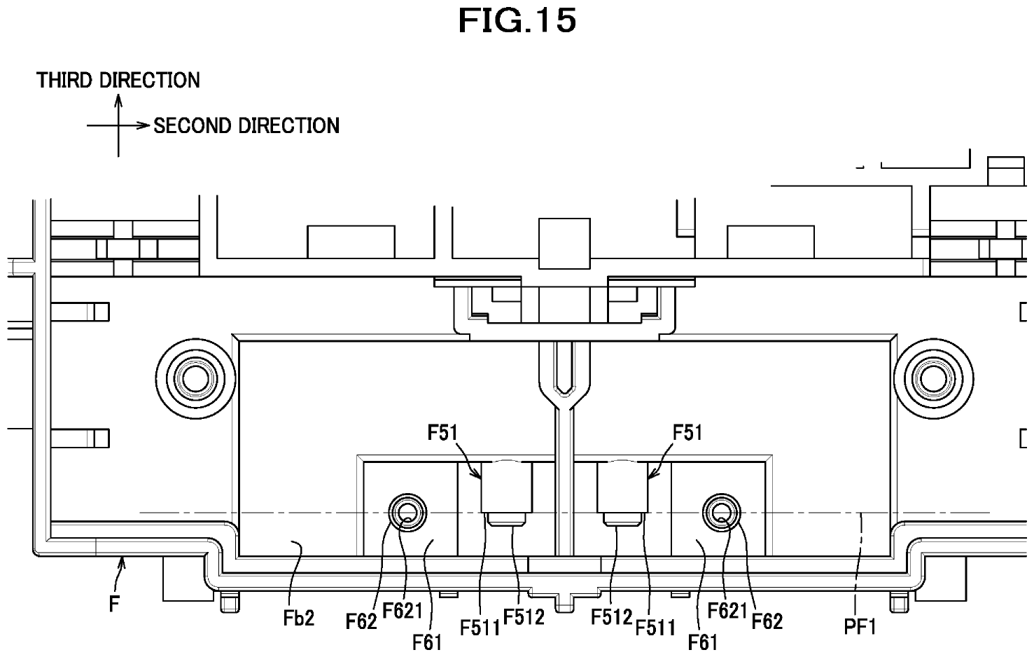

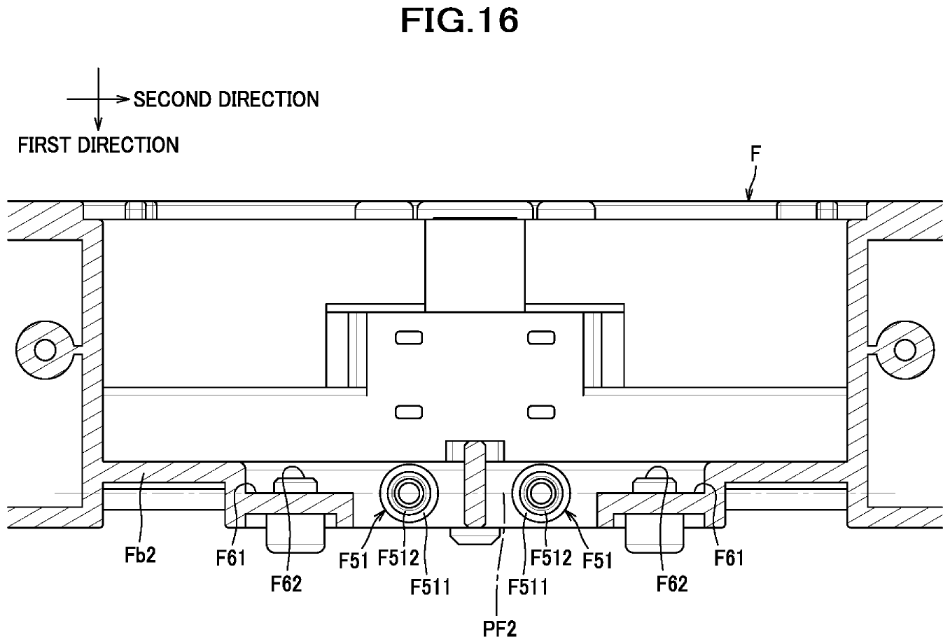

As shown in FIG. 15 and FIG. 16, the second base wall Fb2 of the frame F has two second locating surfaces F61 with which the lens holder H2 is positioned in the first direction, and includes two cylindrical second bosses F62 with which the lens holder H2 is positioned in the third direction. The second locating surfaces F61 face in the direction opposite to the first direction. When the lens holder H2 has been attached to the frame F, the second locating surfaces F61 contact the locating surfaces H23 of the lens holder H2.

The second bosses F62 serve as an example of a second restraining portion, and protrude from the second locating surfaces F61 in the direction opposite to the first direction. When the lens holder H2 has been attached to the frame F, the second bosses F62 are fitted in the locating holes H24 of the lens holder H2.

A hole F621 configured to allow a screw N1 to be inserted therein is formed at a center of an end face of each second boss F62. When the lens holder H2 has been attached to the frame F, the end portions of the legs H22 are each held between the head of the corresponding screw N1 and the corresponding second locating surface F61 (see FIGS. 17A and 17B).

As shown in FIG. 15, the second bosses F62 and the second locating surfaces F61 intersect with a first plane PF1 containing the aforementioned first locating surfaces F511. To be more specific, the first plane PF1 is an imaginary plane which is defined by extending the first locating surfaces F511, and thus parallel to and inclusive of the first locating surfaces F511. In this example, the second locating surfaces F61 are perpendicular to the first plane PF1. The first plane PF1 intersects with the centers of the second bosses F62.

As shown in FIG. 16, the protrusions F512 of the first bosses F51 and the first locating surfaces F511 intersect with a second plane PF2 containing the second locating surfaces F61. To be more specific, the second plane PF2 is an imaginary plane which is defined by extending the second locating surfaces F61, and thus parallel to and inclusive of the second locating surfaces F61. In this example, the first locating surfaces F511 are perpendicular to the second plane PF2. The second plane PF2 intersects with the centers of the first bosses F51.

Next, a description will be given of a method for making a scanning optical device 1. Specifically, a method of attaching coupling lenses 20 to a frame F will be described below.

To attach coupling lenses 20 to a frame F, first, the laser holders H11 and H12 in which the semiconductor lasers 10 are held are attached to the frame F by screws N as shown in FIG. 7, and then a first bonding process as shown in FIGS. 10A and 10B is executed. Thereafter, an attaching process as shown in FIGS. 17A and 17B is executed, and then a second bonding process as shown in FIGS. 17B and 17C is executed.

As shown in FIGS. 17A and 17B, the attaching process comprises attaching the lens holder H2 to the frame F by screws N1. Operations of attaching the lens holder H2 and tightening the screws N1 may be performed manually or by using a specifically designed machine.

As shown in FIG. 17B, the second bonding process comprises holding the second coupling lens 20M by using a jig J at two ends thereof facing in opposite directions parallel to the second direction. The second bonding process further comprises placing a not-yet-cured photo-curable resin P between the second coupling lens 20M and the second seating surface Hf21 of the lens holder H2. In the example illustrated in FIG. 17B, the photo-curable resin P is applied on the second seating surface Hf21 of the lens holder H2, before the second coupling lens 20M is brought close to the second seating surface Hf21.

Next, the jig J is moved in the first direction, to move the second coupling lens 20M in the first direction through an open side of the frame F which opens in the direction opposite to the first direction, thereby bringing the second coupling lens 20M close to the second seating surface Hf21, until the photo-curable resin P is sandwiched between the second coupling lens 20M and the second seating surface Hf21. Thereafter, a position of the second coupling lens 20M relative to the second semiconductor laser 10M is adjusted by moving the jig J in the first direction, the second direction, and/or the third direction.

After completion of adjustment of the position of the second coupling lens 20M, light is applied to the photo-curable resin P to bond and fix the second coupling lens 20M to the second seating surface Hf21 of the lens holder H2, as shown in FIG. 17C. The third coupling lens 20C is bonded and fixed to the second seating surface Hf22 of the lens holder H2 by the same method as the above-described method of attaching the second coupling lens 20M to the second seating surface Hf21 of the lens holder H2.

In the modified example as described above, the following advantageous effects can be achieved.

Since a plurality of coupling lenses 20 can be attached on one and the same side, complicated work can be obviated in the process of making the scanning optical device 1.

Since the leg H22 extending from the base H21 is provided in the lens holder H2, an undesirable collision of the base H21 with the first coupling lens 20Y can be made less likely to occur.

Since the two legs H22A, H22B of the lens holder H2 are fixed to the frame F, the second coupling lens 20M can be held stably by the lens holder H2.

Since the portion which holds the first semiconductor laser 10Y and the seating surface Hf1 on which the first coupling lens 20Y is fixed are integrally formed of a single part, the first coupling lens 20Y can be located in place relative to the first semiconductor laser 10Y with increased precision.

Since the second bosses F62 intersect with the first plane PF1, the second bosses F62 and the first locating surfaces F511 are arranged, in alignment with each other, in approximately the same position with respect to the positions in the third direction; therefore, the influence of thermal expansion of the holders H11, H12, and H2 on positioning accuracy in the third direction can be reduced.

Further, the frame F comprises the protrusions F512 (of the first bosses F51) with which the first laser holders H11, H12 are positioned in the first direction, and the second locating surfaces F61 with which the lens holder H2 is positioned in the third direction, wherein the protrusions F512 are located in such positions that the second plane PF2 containing the second locating surfaces F61 intersects with the protrusions F512.

Since the protrusions F512 of the first bosses F51 intersect with the second plane PF2, the protrusions F512 and the second locating surfaces F61 are arranged, in alignment with each other, in approximately the same position with respect to the positions in the first direction; therefore, the influence of thermal expansion of the holders H11, H12, and H2 on positioning accuracy in the first direction can be reduced.

Since the second coupling lens 20M and the third coupling lens 20C are fixed on the second seating surfaces Hf21 and Hf22 of the lens holder H2, the number of parts can be reduced in comparison with an alternative configuration, for example, in which the third coupling lens is fixed to another member provided separately from a member which holds the second coupling lens.

Since all of the first laser holder H11, the second laser holder H12, and the lens holder H2 are made of plastic, the first laser holder H11, the second laser holder H12, and the lens holder H2 can be formed to have the same linear expansivity; therefore, undesirable deviation in relative positions of the four coupling lenses 20 due to thermal expansion of the first laser holder H11, the second laser holder H12, and the lens holder H2 can be minimized. Furthermore, variations of refractive powers and diffractive powers of the four coupling lenses 20 due to change in temperature can be compensated for by making use of the linear expansivities of first laser holder H11, the second laser holder H12, and the lens holder H2.

This modified example as well as the above-described embodiment may be implemented in various other forms as will be illustrated below.

The second holder may be fixed to the frame by any method other than that which uses a screw; for example, the fixing of the second holder to the frame may be done by using an adhesive, or fitting the corresponding mating portions thereof.

The first seating surfaces and the second seating surfaces may be perpendicular to the second direction.

The above-illustrated configurations in which the protrusion F512 serves as the first restraining portion, and the second boss F62 serves as the second restraining portion is presented by way of example only. The restraining portions may be configured to have any other shape, such as a recess, a hole, etc. The first predetermined direction and the second predetermined direction may be directions other than those described above.

The number of legs of the second holder may be one, three or more.

Any of the elements explained in relation to the embodiment and illustrative modified examples disclosed in this description may be implemented in combination as desired.

What is claimed is:

1. A scanning optical device, comprising:
a first semiconductor laser configured to emit light;
a second semiconductor laser configured to emit light;
a first coupling lens configured to convert the light emitted by the first semiconductor laser into a light beam;
a second coupling lens configured to convert light emitted by the second semiconductor laser into a light beam;
a polygon mirror configured to deflect the light beam received from the first coupling lens and the light beam received from the second coupling lens;
a first holder configured to hold the first coupling lens, the first holder having a seating surface on which the first coupling lens is fixed by a photo-curable resin; and
a second holder configured to hold the second coupling lens in such a position that the first coupling lens and the second coupling lens are arranged in a line parallel to a rotation axis of the polygon mirror, the second holder being fixed to the first holder by a photo-curable resin.

2. The scanning optical device according to claim 1, wherein the seating surface is a flat surface perpendicular to the rotation axis.

3. The scanning optical device according to claim 1, wherein the second holder comprises:
a lens attachment to which the second coupling lens is attached; and
a leg extending from the lens attachment to the seating surface, the leg being fixed on the seating surface by a photo-curable resin.

4. The scanning optical device according to claim 3, wherein the leg comprises a first leg and a second leg located in a position, separate from the first leg in a perpendicular direction perpendicular to the rotation axis and to an optical axis of the first semiconductor laser, such that light traveling from the first semiconductor laser to the first coupling lens passes through a gap formed between the first leg and the second leg.

5. The scanning optical device according to claim 1, wherein the second holder is made of a material that allows light for curing the photo-curable resin to pass therethrough.

6. The scanning optical device according to claim 1, wherein the first holder holds the first semiconductor laser and the second semiconductor laser arranged in a line parallel to the rotation axis of the polygon mirror, and
wherein the first holder comprises:
a first portion having the seating surface; and
a second portion extending from the first portion in a direction parallel to the rotation axis, the second portion being configured to hold the first semiconductor laser and the second semiconductor laser.

7. The scanning optical device according to claim 1, wherein the first holder and the second holder are made of plastic.

8. A method for making a scanning optical device having a first semiconductor laser, a second semiconductor laser, a first coupling lens, a second coupling lens and a polygon mirror, in which light emitted by the first semiconductor laser is converted by the first coupling lens into a light beam and light emitted by the second semiconductor laser is converted by the second coupling lens into a light beam, and the light beams received from the first coupling lens and the second coupling lens are deflected by the polygon mirror, the method comprising:
providing a first holder configured to hold the first coupling lens, the first holder having a seating surface;
providing a second holder configured to hold the second coupling lens, in such a position that the first coupling lens and the second coupling lens are arranged in a line parallel to a rotation axis of the polygon mirror;
locating the first coupling lens in place relative to the first semiconductor laser, and fixing the first coupling lens to the seating surface of the first holder;
attaching the second coupling lens to the second holder; and
locating the second coupling lens attached to the second holder in place relative to the second semiconductor laser, and fixing the second holder to the first holder.

9. The method according to claim 8, wherein
the locating and fixing the first coupling lens comprises:
placing a photo-curable resin between the first coupling lens and the seating surface; and
adjusting a position of the first coupling lens relative to the first semiconductor laser, and thereafter applying light to the photo-curable resin to fix the first coupling lens to the seating surface, and
the locating the second coupling lens and fixing the second holder comprises:
placing a photo-curable resin between the first holder and the second holder; and
adjusting a position of the second coupling lens relative to the second semiconductor laser, and thereafter applying light to the photo-curable resin to fix the second holder to the first holder.

10. The method according to claim 8, wherein the locating the first coupling lens in place comprises adjusting a position of the first coupling lens relative to the first semiconductor laser by using a jig holding the first coupling lens at two ends thereof facing in opposite directions parallel to a perpendicular direction perpendicular to the rotation axis and to an optical axis of the first semiconductor laser.

11. The method according to claim 10, wherein the locating the second coupling lens in place comprises adjusting a position of the second coupling lens relative to the second semiconductor laser by using the jig holding the second holder at two ends thereof facing in opposite directions parallel to the perpendicular direction.

12. A scanning optical device comprising:
a first semiconductor laser configured to emit light;
a second semiconductor laser configured to emit light;
a first coupling lens configured to convert the light emitted by the first semiconductor laser into a light beam;
a second coupling lens configured to convert the light emitted by the second semiconductor laser into a light beam;
a deflector comprising a polygon mirror configured to deflect the light beam received from the first coupling lens and the light beam received from the second coupling lens;
a frame to which the deflector is fixed;
a first holder configured to hold the first coupling lens, the first holder having a first seating surface on which the first coupling lens is fixed by a photo-curable resin; and
a second holder configured to hold the second coupling lens, in such a position that the first coupling lens and the second coupling lens are arranged in a line parallel to a rotation axis of the polygon mirror, the second holder having a second seating surface on which the second coupling lens is fixed by a photo-curable resin, the second holder being fixed to the frame.

13. The scanning optical device according to claim 12, wherein each of the first seating surface and the second seating surface is a flat surface perpendicular to the rotation axis.

14. The scanning optical device according to claim 12, wherein the second holder comprises:
a base having the second seating surface; and
a leg extending from the base in a direction opposite to a direction in which the second seating surface faces, the leg being fixed to the frame.

15. The scanning optical device according to claim 14, wherein the leg comprises a first leg and a second leg located in a position, separate from the first leg in a perpendicular direction perpendicular to the rotation axis and to an optical axis of the first semiconductor laser, such that light traveling from the first semiconductor laser to the first coupling lens passes through a gap formed between the first leg and the second leg.

16. The scanning optical device according to claim 12, wherein the first holder holds the first semiconductor laser and the second semiconductor laser arranged in a line parallel to the rotation axis of the polygon mirror, and
wherein the first holder comprises:
a first portion having the first seating surface; and
a second portion extending from the first portion in a direction parallel to the rotation axis, the second portion being configured to hold the first semiconductor laser and the second semiconductor laser.

17. The scanning optical device according to claim 12, wherein the frame comprises:
a first locating surface with which the first holder is positioned in a first predetermined direction; and
a second restraining portion with which the second holder is positioned in the first predetermined direction, the second restraining portion being located in such a position that a first plane containing the first locating surface intersects with the second restraining portion.

18. The scanning optical device according to claim 12, wherein the frame comprises:
a first restraining portion with which the first holder is positioned in a second predetermined direction; and
a second locating surface with which the second holder is positioned in the second predetermined direction, the first restraining portion being located in such a position that a second plane containing the second locating surface intersects with the first restraining portion.

19. The scanning optical device according to claim 12, wherein the second holder is fixed to the frame with a screw.

20. The scanning optical device according to claim 12, further comprising:
a third semiconductor laser configured to emit light;
a fourth semiconductor laser configured to emit light;
a third coupling lens configured to convert the light emitted by the third semiconductor laser into a light beam; and
a fourth coupling lens configured to convert the light emitted by the fourth semiconductor laser into a light beam,
wherein the second semiconductor laser and the third semiconductor laser are arranged in a line parallel to a perpendicular direction perpendicular to an optical axis of the first semiconductor laser and to the rotation axis, the first semiconductor laser and the fourth semiconductor laser are arranged in a line parallel to the perpendicular direction, and the third semiconductor laser and the fourth semiconductor laser are arranged in a line parallel to the rotation axis, and
wherein the third coupling lens is fixed on the second seating surface by a photo-curable resin.
